(19) United States
(12) Patent Application Publication
(10) Pub. No.: US 2025/0006816 A1
(43) Pub. Date: Jan. 2, 2025

(54) STACKED DEVICE WITH NITROGEN-CONTAINING INTERFACIAL LAYER AND MANUFACTURING METHOD THEREOF

(71) Applicant: TAIWAN SEMICONDUCTOR MANUFACTURING COMPANY, LTD., Hsinchu (TW)

(72) Inventors: Wei-Hsiang LIN, New Taipei City (TW); Shu-Han CHEN, Hsinchu City (TW); Chi On CHUI, Hsinchu City (TW)

(73) Assignee: TAIWAN SEMICONDUCTOR MANUFACTURING COMPANY, LTD., Hsinchu (TW)

(21) Appl. No.: 18/345,634

(22) Filed: Jun. 30, 2023

(51) Int. Cl. H01L 29/66; H01L 21/8238; H01L 27/092; H01L 29/06; H01L 29/423; H01L 29/775; H01L 29/786

(52) U.S. Cl. CPC H01L 29/66545; H01L 21/823807; H01L 21/823814; H01L 27/0924; H01L 29/0673; H01L 29/42392; H01L 29/66439; H01L 29/775; H01L 29/78696

(57) ABSTRACT

A method includes forming a fin structure including first and second sacrificial layers and first and second channel layers over a substrate; forming a dummy gate structure across the fin structure; forming gate spacers on opposite sides of the dummy gate structure; forming first source/drain epitaxial layers on opposite sides of the first channel layer; forming second source/drain epitaxial layers on opposite sides of the second channel layer; removing the dummy gate structure and the first and second sacrificial layers to form a gate trench defined by the gate spacers; forming an oxynitride layer in the gate trench to surround the first channel layer; forming a dipole layer to surround the oxynitride layer; performing an anneal process to drive dipole dopants into the oxynitride layer; and depositing a high-k gate dielectric layer and a work function metal layer in the gate trench to form a gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process can increase production efficiency and lower associated costs. Such scaling down has also increased the complexity of processing and manufacturing ICs and, for these advancements to be realized, similar developments in IC processing and manufacturing are desired. As the semiconductor industry further progresses in pursuit of higher device density, challenges from both fabrication and design issues have led to stacked device structure configurations, such as complementary field effect transistors (C-FET).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-16B illustrate perspective views and cross-sectional views of intermediate stages in the formation of an integrated circuit structure (or a semiconductor device) in accordance with some embodiments of the present disclosure.

FIGS. 17-29B illustrate perspective views and cross-sectional views of intermediate stages in the formation of an integrated circuit structure (or a semiconductor device) in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure.

These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “etch selectivity” refers to the ratio of the etch rates of two different materials under the same etching conditions. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9). As used herein, the term “low-k” refers to a low dielectric constant. In the field of semiconductor device structures and manufacturing processes, low-k refers to a dielectric constant that is less than the dielectric constant of SiO₂ (e.g., less than 3.9). As used herein, the term “p-type” defines a structure, layer, and/or region as being doped with p-type dopants, such as boron. As used herein, the term “n-type” defines a structure, layer, and/or region as being doped with n-type dopants, such as phosphorus. As used herein, the term “conductive” refers to an electrically conductive structure, layer, and/or region. As used herein, source/drain region(s) may refer to a source or a drain, individually or collectively dependent upon the context.

The nanostructure transistor (e.g. gate all around (GAA) transistor) structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit structures and methods of forming the same. More particularly, some embodiments of the present disclosure are related to complementary FET (CFET) devices including a plasma-formed interfacial layer under a dipole layer. The plasma-formed interfacial layer prevents atoms in the dipole layer from diffusing deep into a channel layer of the CFET.

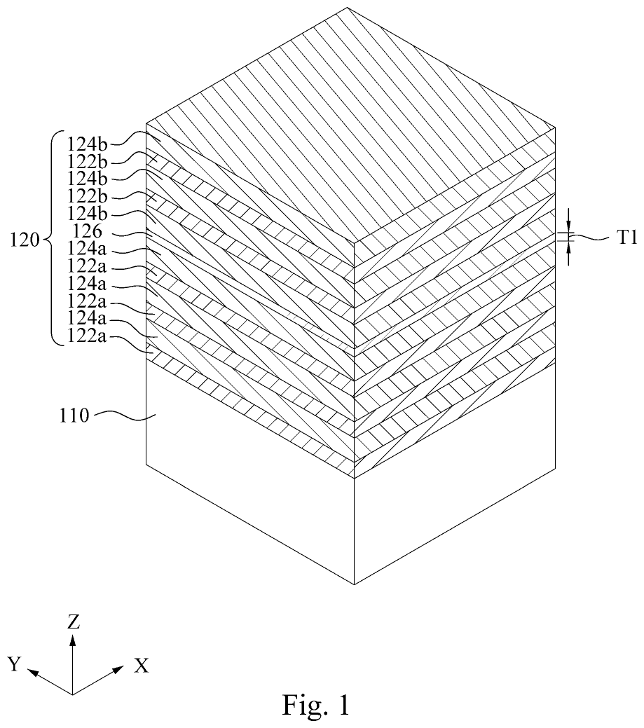

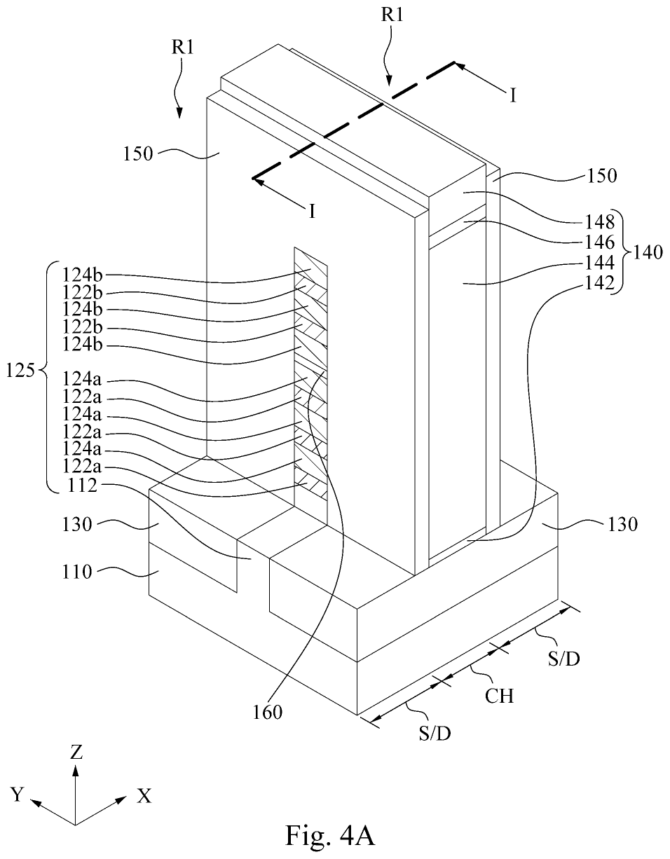

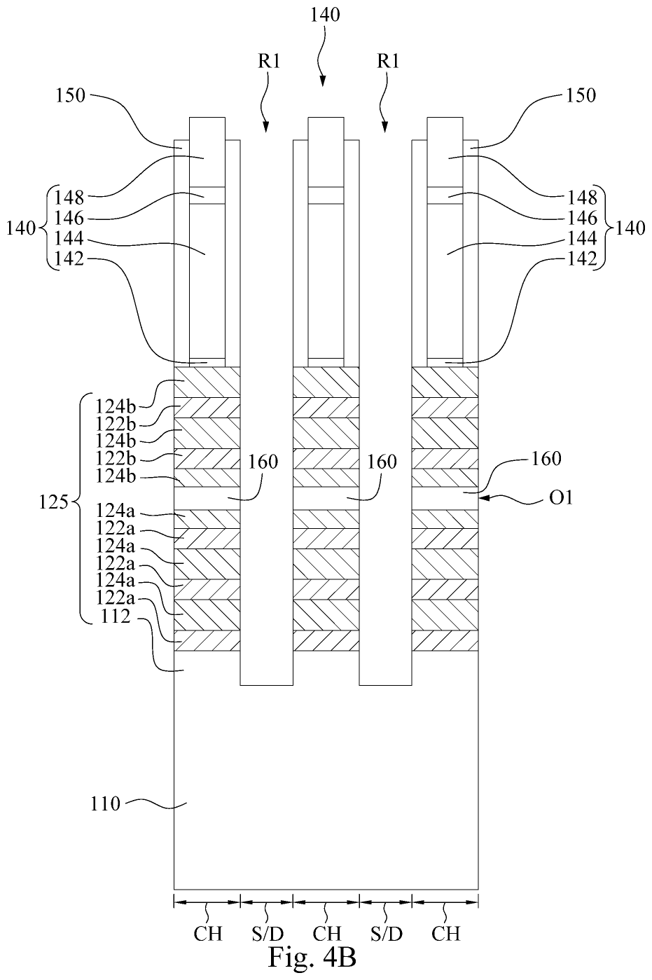

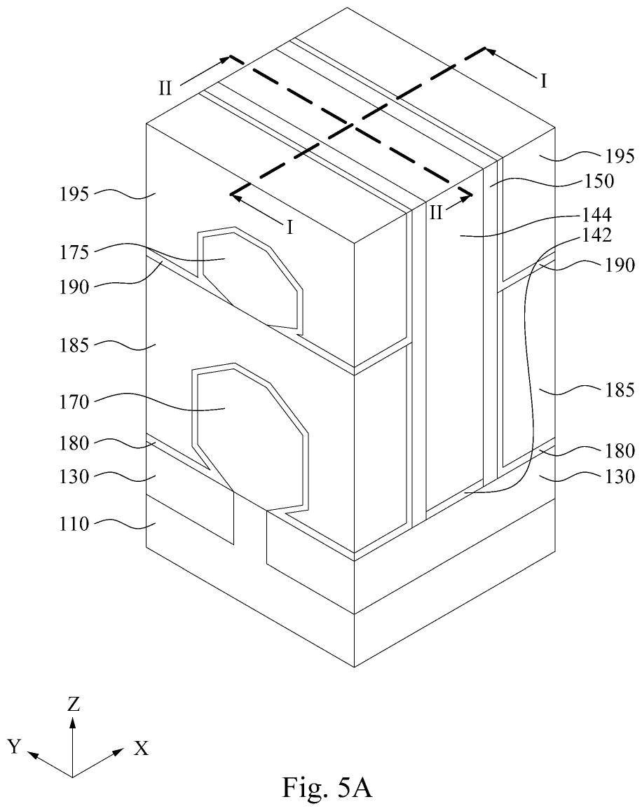

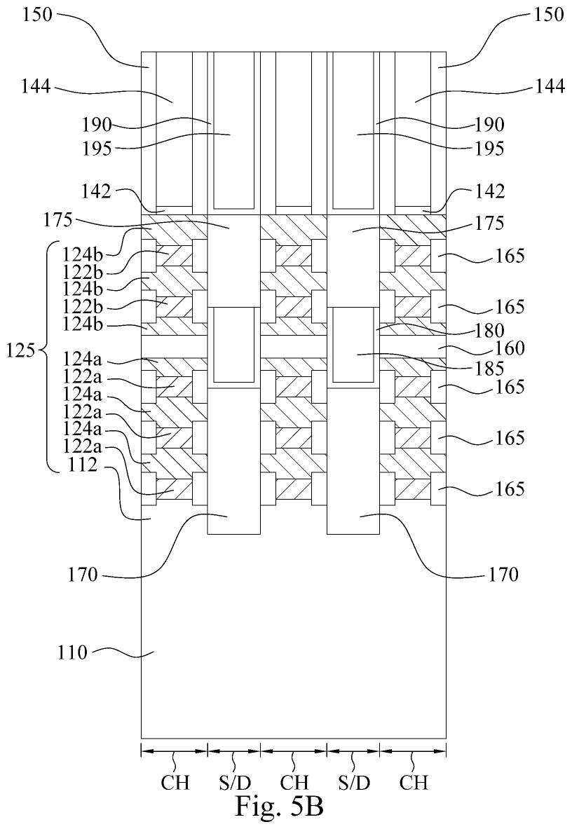

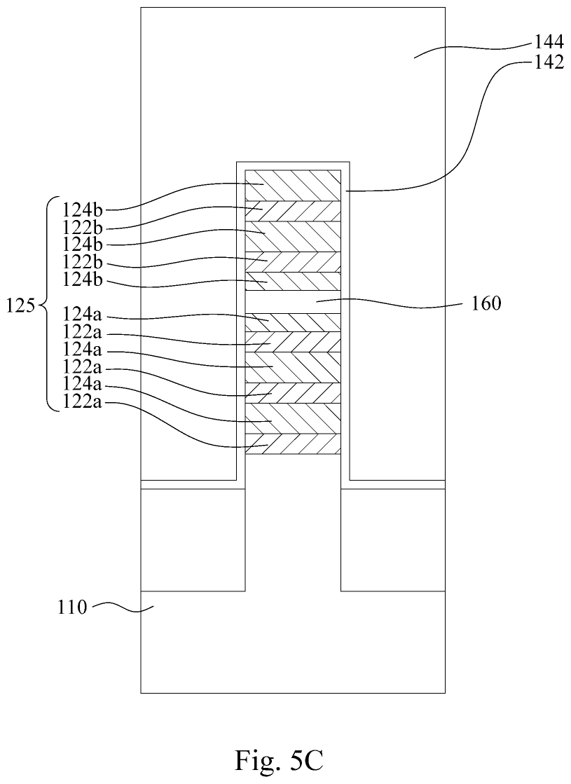

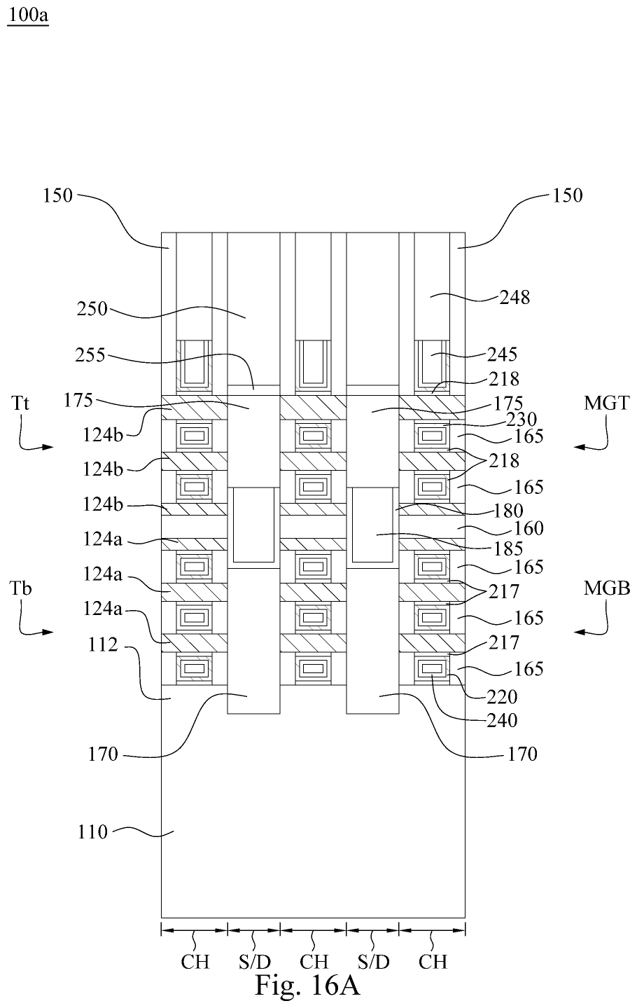

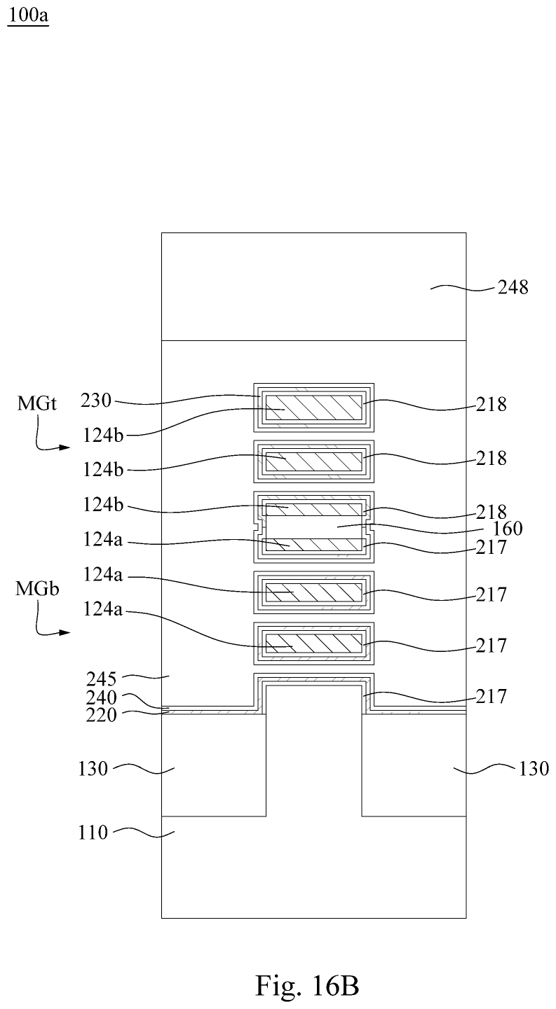

FIGS. 1-16B illustrate perspective views and cross-sectional views of intermediate stages in the formation of an integrated circuit structure (or a semiconductor device) 100a in accordance with some embodiments of the present disclosure. In some embodiments, the semiconductor device in FIGS. 16A and 16B is a CFET device. In addition to the integrated circuit structure 100a, FIGS. 1-4A, and 5A depict X-axis, Y-axis, and Z-axis directions. FIGS. 4B, 5B, 6A, 7A, 8A, 9A, 10A, 11A, 12A, 13A, 14A, 15A, and 16A are cross-sectional views of some embodiments of the integrated circuit structure 100a at intermediate stages along a first cut (e.g., cut I-I in FIG. 4A). FIGS. 5C, 6B, 7B, 8B, 9B, 10B, 11B, 12B, 13B, 14B, 15B, and 16B are cross-sectional views of some embodiments of the integrated circuit structure 100a at intermediate stages along a second cut (e.g., cut II-II in FIG. 5A). The formed devices include a p-type transistor (such as a p-type GAA FET) and an n-type transistor (such as an n-type GAA FET) in accordance with some exemplary embodiments. Throughout the various views and illustrative embodiments, like reference numbers are used to designate like elements. It is understood that additional operations can be provided before, during, and after the processes shown by FIGS. 1-16B, and some of the operations described below can be replaced or eliminated, for additional embodiments of the method. The order of the operations/processes may be interchangeable.

Referring to FIG. 1, an epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or combinations thereof) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or another appropriate method.

The epitaxial stack 120 includes epitaxial layers 122a and 122b of a first composition interposed by epitaxial layers 124a and 124b of a second composition arranged in a stacking direction (Z-axis in this case). The epitaxial stack 120 further includes an epitaxial layer 126 between the topmost epitaxial layer 124a and the bottommost epitaxial layer 124b of a third composition. The first, second, and third compositions are different. In some embodiments, the epitaxial layers 122a, 122b, and 126 are SiGe and the epitaxial layers 124a and 124b are silicon (Si). Further, the germanium concentration of the epitaxial layer 126 is higher than the germanium concentration of the epitaxial layer 122a and 122b. However, other embodiments are possible including those that provide for a first composition, a second composition, and a third composition having different etch selectivity.

The epitaxial layers 124a and 124b or portions thereof may form nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the epitaxial layers 124a and 124b to define a channel or channels of a device is further discussed below.

In FIG. 1, the epitaxial layers 124b are disposed above the epitaxial layers 124a. It is noted that three layers of the epitaxial layers 124a and three layers of the epitaxial layers 124b are arranged as illustrated in FIG. 1, which is for illustrative purposes only and not intended to be limiting beyond what is specifically recited in the claims. It can be appreciated that any number of epitaxial layers can be formed in the epitaxial stack 120; the number of layers depending on the desired number of channels regions for the transistor. In some embodiments, the number of each of the epitaxial layers 124a and 124b is between 2 and 10.

The epitaxial layers 122a are interposed by the epitaxial layers 124a, the epitaxial layers 122b are interposed by the epitaxial layers 124b, and the epitaxial layer 126 is between the epitaxial layers 124a and 124b. In some embodiments, the epitaxial layer 126 has a thickness T1 less than the thicknesses of the epitaxial layers 122a, 122b, 124a, and 124b.

As described in more detail below, the epitaxial layers 124a and 124b may serve as channel region(s) for a subsequently-formed semiconductor device and the thickness is chosen based on device performance considerations. The epitaxial layers 122a and 122b in channel regions(s) may eventually be removed and serve to define a vertical distance between adjacent channel region(s) for a subsequently-formed multi-gate device and the thickness is chosen based on device performance considerations. Accordingly, the epitaxial layers 122a and 122b may also be referred to as sacrificial layers, and epitaxial layers 124a and 124b may also be referred to as channel layers.

By way of example, epitaxial growth of the layers of the epitaxial stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124a and 124b include the same material as the substrate 110. In some embodiments, the epitaxial layers 122a, 122b, 124a, 124b, and 126 include a different material than the substrate 110. As stated above, in at least some examples, the epitaxial layers 122a, 122b, and 126 include an epitaxially grown silicon germanium (SiGe) layer and the epitaxial layers 124a and 124b include an epitaxially grown silicon (Si) layer. Alternatively, in some embodiments, either of the epitaxial layers 122a, 122b, 124a, 124b, and 126 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the epitaxial layers 122a, 122b, 124a, 124b, and 126 may be chosen based on providing differing oxidation and/or etching selectivity properties.

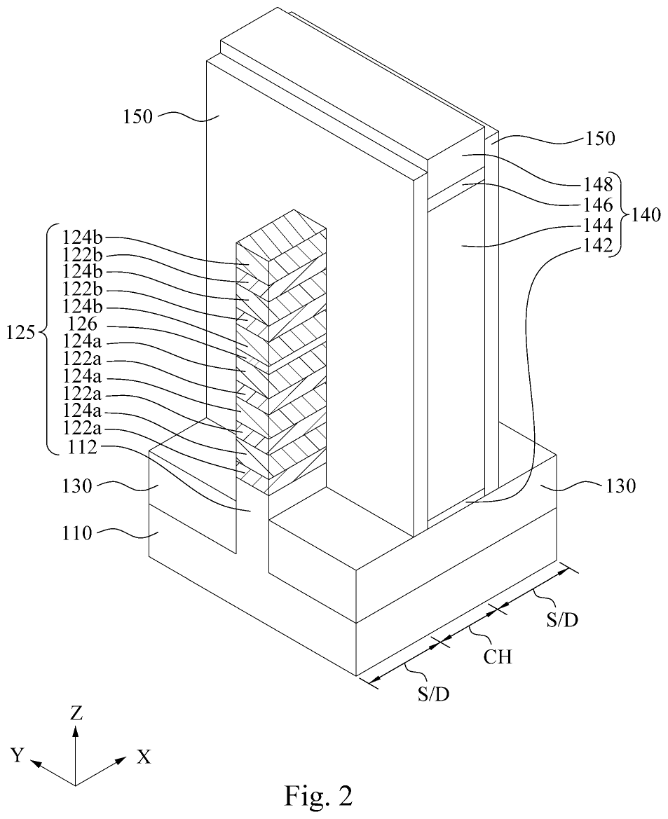

Reference is made to FIG. 2. At least one fin structure 125 extending from the substrate 110 is formed. In various embodiments, the fin structure 125 includes a protruding portion 112 formed from the substrate 110 and portions of each of the epitaxial layers of the epitaxial stack including epitaxial layers 122a, 122b, 124a, 124b, and 126. The fin structure 125 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin structure 125 by etching the epitaxial stack 120. The etching process can include dry etching, wet etching, reactive ion etching (RIE), and/or other suitable processes.

For example, a hard mask (HM) layer is formed over the epitaxial stack 120 prior to forming the fin structure 125. The fin structure 125 may subsequently be fabricated using suitable processes including photolithography and etch processes. The photolithography process may include forming a photoresist layer (not shown) over the HM layer, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process using light in EUV region, having a wavelength of, for example, about 1-200 nm. The patterned mask may then be used to protect regions of the substrate 110, and layers formed thereupon, while an etch process forms trenches in unprotected regions through the HM layer, through the epitaxial stack 120, and into the substrate 110, thereby leaving the fin structure 125. The trenches may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fin structure 125.

Next, isolation structures 130 are formed to surround the fin structure 125. The isolation structures 130 may include a liner oxide (not shown). The liner oxide may be formed of a thermal oxide formed through a thermal oxidation of a surface layer of the substrate 110. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The isolation structures 130 may also include a dielectric material over the liner oxide, and the dielectric material may be formed using flowable chemical vapor deposition (FCVD), spin-on coating, or the like.

The isolation structures 130 are then planarized, such that the HM layer is removed, and the top surface of the fin structure 125 is exposed. Subsequently, the isolation structures 130 are recessed, so that the top portion of the fin structure 125 protrudes higher than the top surfaces of the neighboring isolation structures 130. The etching may be performed using a dry etching process, wherein NH₃ and NF₃ are used as the etching gases. During the etching process, plasma may be generated. Argon may also be included. In accordance with alternative embodiments of the present disclosure, the recessing of the isolation structures 130 is performed using a wet etch process. The etching chemical may include diluted HF, for example.

At least one dummy gate structure 140 is formed over the substrate 110 and across the fin structure 125. The portion of the fin structure 125 underlying the dummy gate structure 140 may be referred to as the channel region CH. The dummy gate structure 140 may also define source/drain regions S/D of the fin structure 125, for example, the regions of the fin structure 125 adjacent and on opposite sides of the channel region CH.

Dummy gate formation operation forms a dummy gate dielectric layer, a dummy gate electrode layer and a hard mask which may include multiple layers (e.g., a nitride layer and an oxide layer) over the dummy gate electrode layer. The hard mask is then patterned, followed by patterning the dummy gate electrode layer by using the patterned hard mask as an etch mask. The etch process may include a wet etch, a dry etch, and/or combinations thereof. As such, a dummy gate structure 140 including a dummy gate dielectric layer 142, a dummy gate electrode layer 144 and a hard mask (e.g., a nitride layer 146 and an oxide layer 148) is formed.

After formation of the dummy gate structure 140 is completed, gate spacers 150 are formed on opposite sidewalls of the dummy gate structure 140. For example, a spacer material layer is deposited on the substrate 110. The spacer material layer may be a conformal layer that is subsequently etched back to form gate sidewall spacers. In the illustrated embodiment, a spacer material layer is disposed conformally on top and sidewalls of the dummy gate structure 140. The spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as a first spacer layer and a second spacer layer formed over the first spacer layer. By way of example, the spacer material layer may be formed by depositing a dielectric material over the dummy gate structure 140 using suitable deposition processes. An anisotropic etching process is then performed on the deposited spacer material layer to expose portions of the fin structure 125 not covered by the dummy gate structure 140 (e.g., over the source/drain regions S/D of the fin structure 125). Portions of the spacer material layer directly above the dummy gate structure 140 may be completely removed by this anisotropic etching process. Portions of the spacer material layer on sidewalls of the dummy gate structure 140 may remain, forming gate sidewall spacers, which are denoted as the gate spacers 150, for the sake of simplicity.

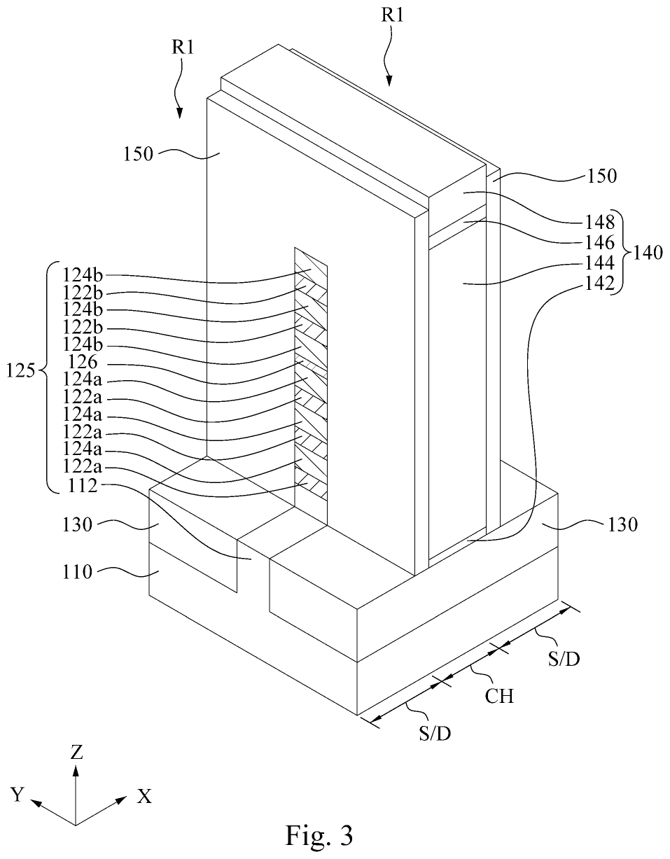

Next, as illustrated in FIG. 3, exposed portions of the fin structure 125 that extend laterally beyond the gate spacers 150 (e.g., in source/drain regions S/D of the fin structure 125) are etched by using, for example, an anisotropic etching process that uses the dummy gate structure 140 and the gate spacers 150 as an etch mask, resulting in recesses R1 into the fin structure 125. After the anisotropic etching, end surfaces of the epitaxial layers 122a, 122b, 124a, 124b, 126 and respective outermost sidewalls of the gate spacers 150 are substantially coterminous, due to the anisotropic etching. In some embodiments, the anisotropic etching may be performed by a dry chemical etch with a plasma source and a reaction gas. The plasma source may be an inductively coupled plasma (ICP) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

Reference is made to FIGS. 4A and 4B, where FIG. 4B is a cross-sectional view taken along line I-I of FIG. 4A. It is noted that in the first cut (line I-I), three dummy gate structures 140 are illustrated to clearly show the detail of the integrated circuit structure 100a. The epitaxial layer 126 is removed, resulting in openings O1 between the topmost epitaxial layers 124a and the bottommost epitaxial layers 124b. In some embodiments, during the selective etching processes, some portions of the epitaxial layers 124a and 124b are also etched. As such, a vertical thickness of the opening O1 is greater than the thickness T1 of the epitaxial layer 126 (see FIG. 1). Subsequently, middle dielectric isolators 160 are filled in the openings O1, respectively, such that the middle dielectric isolators 160 are between the epitaxial layers 124a and 124b. For example, a dielectric material layer is formed to fill the opening O1. The dielectric material layer may be a low-k dielectric material, such as SiO₂, SiN, SiC, SiON, SiCN, or SiOCN, and may be formed by a suitable deposition method, such as ALD. In some embodiments, the dielectric material layer is intrinsic or un-doped with impurities. The dielectric material layer can be formed using CVD, including LPCVD and PECVD, PVD, ALD, or other suitable processes.

After the deposition of the dielectric material layer, an anisotropic etching process may be performed to remove the dielectric material layer outside the openings O1, such that portions of the deposited dielectric material layer that fill the openings O1 are left. After the etching process, the remaining portions of the deposited spacer material in the openings O1 are denoted as the middle dielectric isolators 160, for the sake of simplicity. The middle dielectric isolator 160 serves to isolate the epitaxial layers 124a from the epitaxial layers 124b.

Reference is made to FIGS. 5A-5C, where FIG. 5B is a cross-sectional view taken along line I-I of FIG. 5A, and FIG. 5C is a cross-sectional view taken along line II-II of FIG. 5A. The epitaxial layers 122a and 122b are then laterally or horizontally recessed by using suitable etch techniques, resulting in lateral recesses each vertically between corresponding epitaxial layers 124a and 124b. These operations may be performed by using selective etching processes. In some embodiments, the selective dry etching etches SiGe at a faster etch rate than it etches Si. In some embodiments, during the selective etching processes, some portions of the epitaxial layers 124a and 124b are also etched as shown in FIG. 5B.

Subsequently, inner dielectric spacers 165 are filled in the recesses, respectively. For example, spacer material layers are formed and then trimmed to fill the recesses. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes.

Subsequently, first source/drain epitaxial structures 170, a first contact etch stop layer (CESL) 180, a first interlayer dielectric (ILD) layer 185, second source/drain epitaxial structures 175, a second CESL 190, and a second ILD layer 195 are sequentially formed over the source/drain regions S/D of the fin structure 125. The first source/drain epitaxial structures 170 are on opposite sides and connected to the epitaxial layers 124a and spaced apart from the epitaxial layers 124b. The second source/drain epitaxial structures 175 are on opposite sides and connected to the epitaxial layers 124b and spaced apart from the epitaxial layers 124a. The first source/drain epitaxial structures 170 and second source/drain epitaxial structures 175 may be formed by performing an epitaxial growth process that provides an epitaxial material on the fin structure 125. In some embodiments, the lattice constants of the first source/drain epitaxial structures 170 are different from the lattice constant of the epitaxial layers 124a, so that the epitaxial layers 124a can be strained or stressed by the first source/drain epitaxial structures 170 to improve carrier mobility of the semiconductor device and enhance the device performance. Similarly, the lattice constants of the second source/drain epitaxial structures 175 are different from the lattice constant of the epitaxial layers 124b. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the epitaxial layers 124a or 124b.

In some embodiments, the first source/drain epitaxial structures 170 and the second source/drain epitaxial structures 175 may include Ge, Si, GaAs, AlGaAs, SiGe, GaAsP, SiP, or other suitable material. The first source/drain epitaxial structures 170 and the second source/drain epitaxial structures 175 may be in-situ doped during the epitaxial process by introducing doping species including: p-type dopants, such as boron or BF₂; n-type dopants, such as phosphorus or arsenic; and/or other suitable dopants including combinations thereof. If the first source/drain epitaxial structures 170 and/or the second source/drain epitaxial structures 175 are not in-situ doped, an implantation process (i.e., a junction implant process) is performed to dope the first source/drain epitaxial structures 170 and/or second source/drain epitaxial structures 175. In some exemplary embodiments, the first source/drain epitaxial structures 170 are in an n-type include SiP and/or SiC. In some exemplary embodiments, the second source/drain epitaxial structures 175 are in a p-type include SiGeB and/or GeSnB.

The first CESL 180 is formed on the substrate 110 and covers the first source/drain epitaxial structures 170. The second CESL 190 covers the second source/drain epitaxial structures 175. In some examples, the first CESL 180 and the second CESL 190 include a silicon nitride layer, silicon oxide layer, a silicon oxynitride layer, and/or other suitable materials. The first CESL 180 and the second CESL 190 may be formed by plasma-enhanced chemical vapor deposition (PECVD) process and/or other suitable deposition or oxidation processes.

The first ILD layer 185 is formed over the first CESL 180, and the second ILD layer 195 is formed over the second CESL 190. In some embodiments, the first ILD layer 185 and the second ILD layer 195 include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the first CESL 180. The first ILD layer 185 and the second ILD layer 195 may be deposited by a PECVD process or other suitable deposition technique.

In some examples, after depositing the second ILD layer 195, a planarization process may be performed to remove excessive materials of the second ILD layer 195. For example, a planarization process includes a chemical mechanical planarization (CMP) process which removes portions of the second ILD layer 195 and the second CESL 190 overlying the dummy gate structures 140 and planarizes a top surface of the integrated circuit structure 100a. In some embodiments, the CMP process also removes hard mask layers 146 and 148 (as shown in FIGS. 4A and 4B) and exposes the dummy gate electrode layer 144.

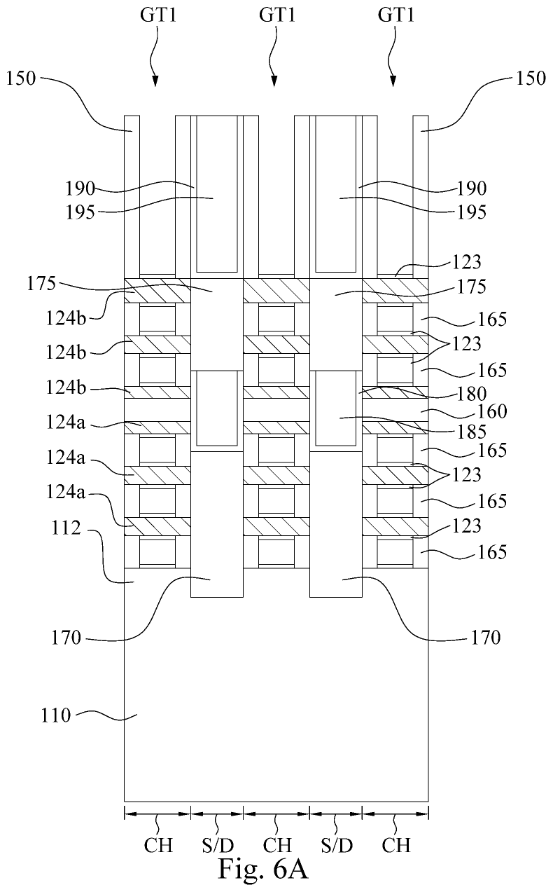

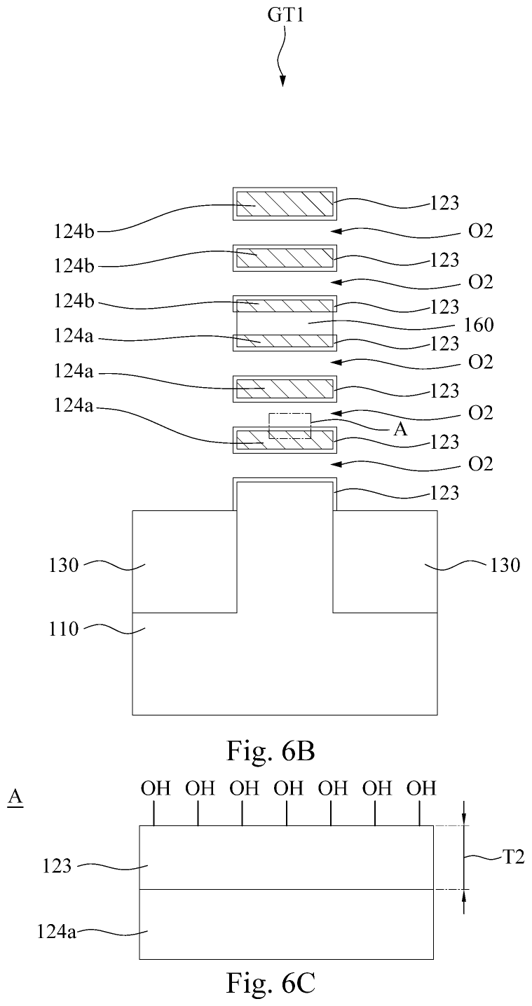

Thereafter, the dummy gate electrode layers 144 are removed first, and then the epitaxial layers (i.e., sacrificial layers) 122a and 122b are removed. The resulting structure is illustrated in FIGS. 6A and 6B. In some embodiments, the dummy gate electrode layer 144 is removed by using a selective etching process (e.g., selective dry etching, selective wet etching, or combinations thereof) that etches the materials in dummy gate electrode layer 144 at a faster etch rate than it etches other materials (e.g., the gate spacers 150 and/or the second ILD layer 195), thus resulting in a gate trench GT1 between the gate spacers 150, with the epitaxial layers 122a and 122b exposed in the gate trench GT1. Subsequently, the epitaxial layers 122a and 122b in the gate trench GT1 are removed by using another selective etching process that etches the epitaxial layers 122a and 122b at a faster etch rate than it etches the epitaxial layers 124a and 124b, thus forming openings O2 between neighboring epitaxial layers (i.e., channel layers) 124a and 124b. In this way, the epitaxial layers 124a and 124b become nanosheets suspended over the substrate 110. This operation is also called a channel release process. In some embodiments, the epitaxial layers 124a and 124b can be interchangeably referred to as nanostructure (nanowires, nanoslabs and nanorings, nanosheet, etc., depending on their geometry). For example, in some other embodiments the epitaxial layers 124a and 124b may be trimmed to have a substantial rounded shape (i.e., cylindrical) due to the selective etching process for completely removing the epitaxial layers 124a and 124b. In that case, the resultant epitaxial layers 124a and 124b can be called nanowires.

In some embodiments, the epitaxial layers 122a and 122b are removed by using a selective dry etching process by using, for example, CF₄ as etching gases. In some embodiments, the epitaxial layers 122a and 122b are SiGe and the epitaxial layers 124a and 124b are silicon allowing for the selective removal of the epitaxial layers 122a and 122b. In some embodiments, during the selective etching processes, some portions of the epitaxial layers 124a and 124b are also etched. As such, vertical thicknesses of the openings O2 are greater than the thicknesses of the epitaxial layers 122a and 122b.

After the removal of the epitaxial layers 122a and 122b, native oxide layers 123 are grown on the exposed surfaces of the epitaxial layers 124a and 124b. Further, as shown in FIG. 6C, which is an enlarged view of the area A in FIG. 6B, OH bonds exist on the exposed surfaces of the native oxide layers 123. The native oxide layers 123 have a thickness T2 as shown in FIG. 6C.

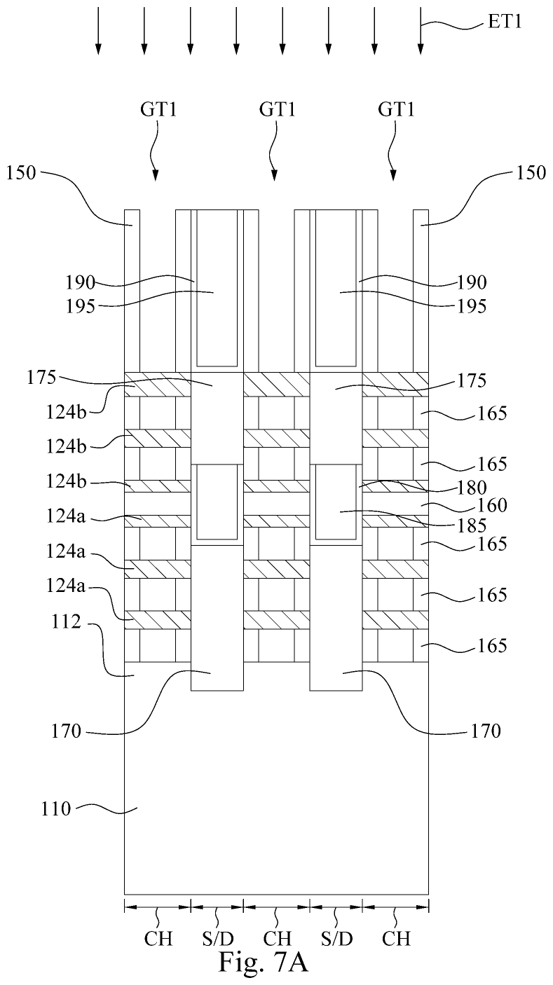

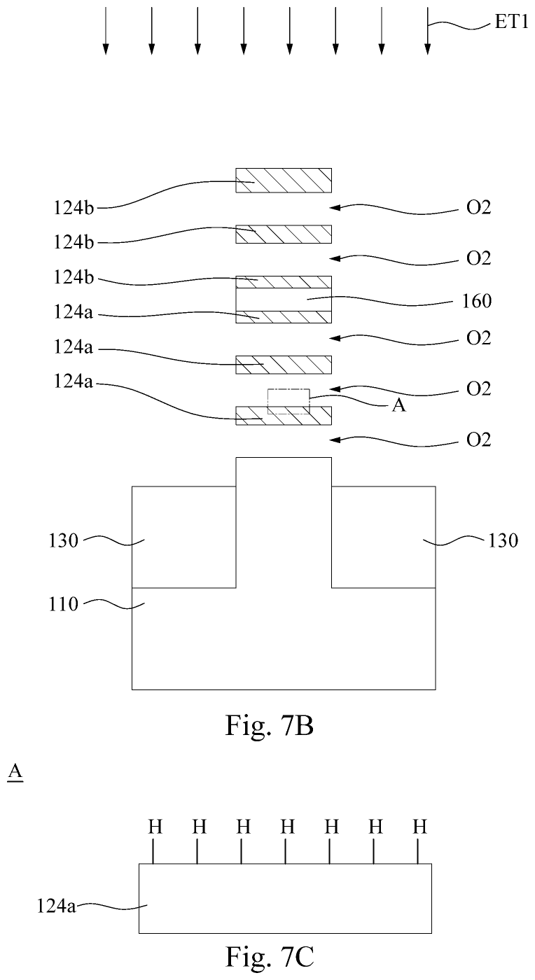

Reference is made to FIGS. 7A and 7B. The native oxide layers 123 are removed from the surfaces of the epitaxial layers 124a and 124b such that the surfaces of the epitaxial layers 124a and 124b are exposed. The native oxide layers 123 may be removed by suitable etching processes including wet etch, dry etch, plasma etch, and/or other suitable processes. In some embodiments, a wet etch including a diluted hydrofluoric acid (dHF) solution is used to remove the native oxide layers 123. As shown in FIG. 7C, which is an enlarged view of the area A in FIG. 7B, after the etching process, the surfaces of the epitaxial layers 124a and 124b are exposed, and hydrogen bonds (which may be from the diluted hydrofluoric acid solution) exist on the surfaces of the epitaxial layers 124a and 124b.

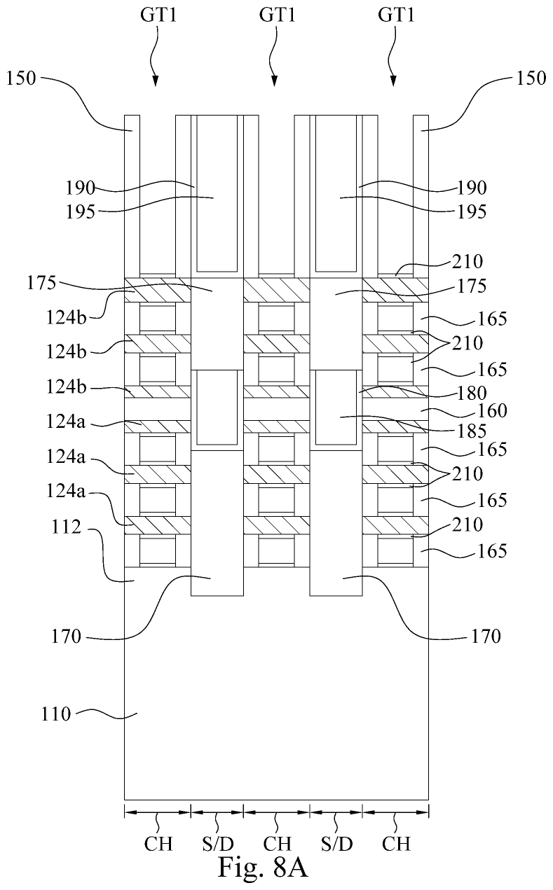

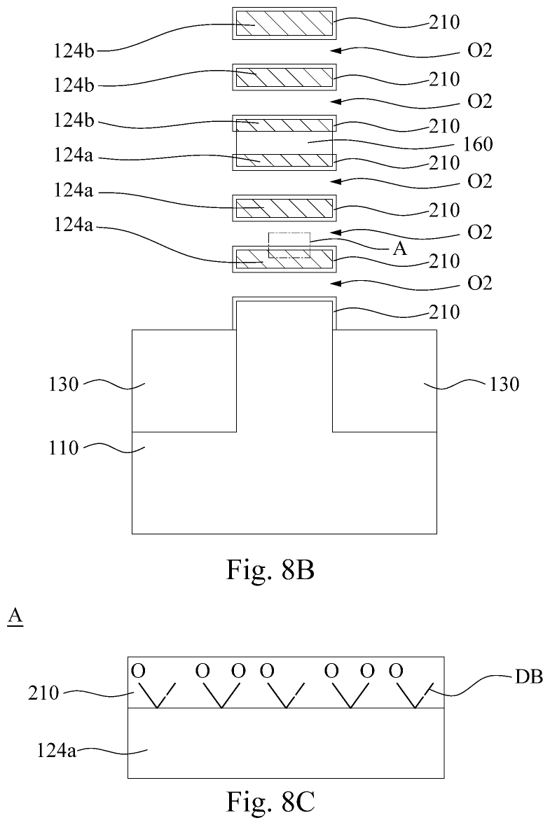

Reference is made to FIGS. 8A and 8B. After the surfaces of the epitaxial layers 124a and 124b are exposed, oxygen atoms in the environment may replace the hydrogen bonds to bond to the atoms in the epitaxial layers 124a and 124b (e.g., Si and/or Ge atoms). As such, oxide layers 210 (e.g., SiO layer) are formed on the surfaces of the epitaxial layers 124a and 124b to surround the epitaxial layers 124a or 124b. As shown in FIGS. 8A and 8B, the oxide layers 210 exposes the surfaces of the inner dielectric spacers 165, the middle dielectric isolators 160, and the isolation structures 130. As shown in FIG. 8C, which is an enlarged view of the area A in FIG. 8B, the oxide layers 210 may include Si—O bonds and some dangling bonds DB. In some embodiments, an amount of oxygen atoms in the oxide layers 210 is greater than an amount of the dangling bonds DB in the oxide layers 210.

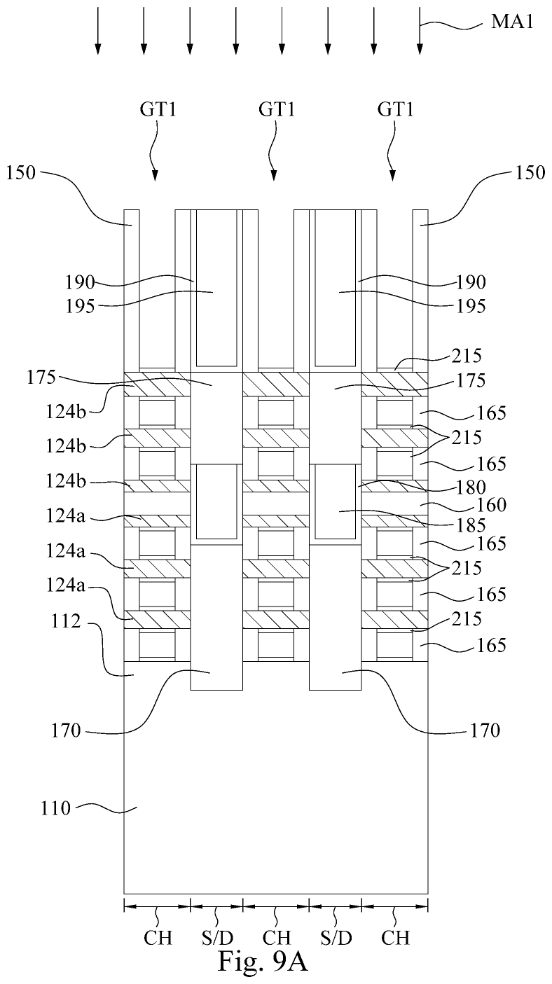

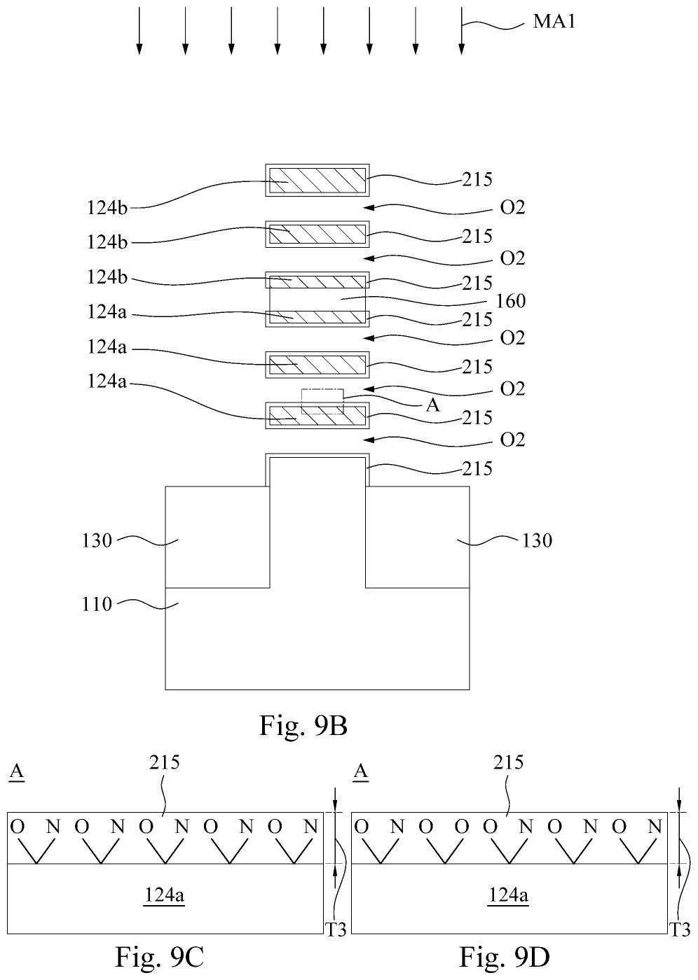

Reference is made to FIGS. 9A and 9B. A microwave annealing MA1 is conducted at a first temperature. In the example shown in FIGS. 9A and 9B, the substrate 110 is annealed using the microwave annealing MA1 at the first temperature. The first temperature is low because the activation energy needed to overcome the energy barrier may come from both the microwave energy and the thermal energy. In some embodiments, the first temperature is lower than about 800° C., for example, about 100° C. to about 500° C. A lower temperature is desired for the microwave annealing MA1 to achieve a median dopant activation level. Dopant loss and dopant diffusion are lower due to the lower temperature.

The microwave annealing MA1 is performed with nitrogen-containing plasma, e.g., NH₃ plasma or the like. For example, NH₃ gases are introduced into a plasma chamber to form the NH₃ plasma, which is then introduced into an anneal apparatus for performing the microwave annealing MAL. As shown in FIGS. 9C and 9D, which are enlarged views of the area A in FIG. 9B in different embodiments, after the microwave annealing process MA1, the dangling bonds DB (see FIG. 8C) are eliminated and nitrogen atoms are bond to the epitaxial layers 124a and 124b. As such, the oxide layers 210 in FIGS. 8A-8C become to be oxynitride layers 215. For example, the oxynitride layers 215 are SiON layers. In some embodiments, the thickness T3 of the oxynitride layers 215 is less than about 50 angstrom, e.g., about 1 angstrom to about 50 angstrom. Further, the thickness T3 is less than the thickness T2. Further, an amount of nitrogen atoms in the oxynitride layers 215 is less than (FIG. 9D) or equal to (FIG. 9C) an amount of oxygen atoms in the oxynitride layers 215. In some embodiments, the oxynitride layers 215 are denoted as (nitrogen-containing) interfacial layers or gate dielectric layers, for the sake of simplicity.

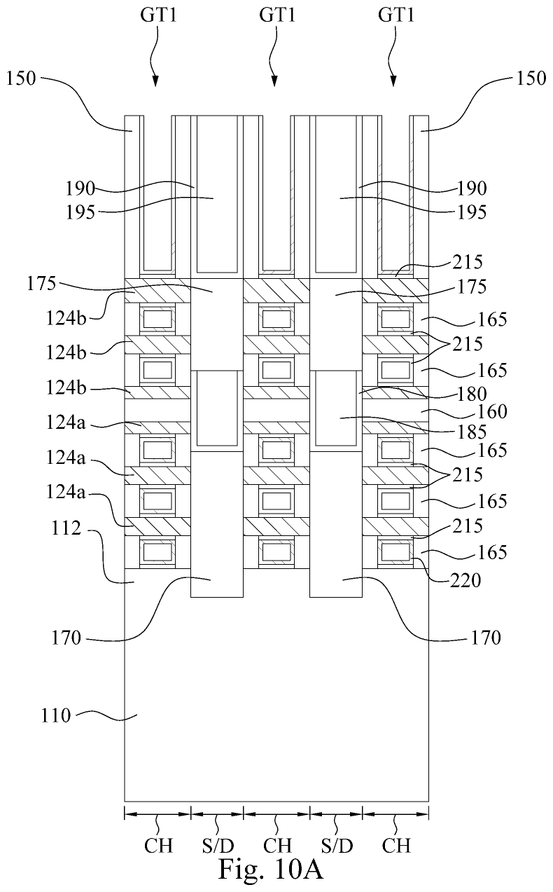

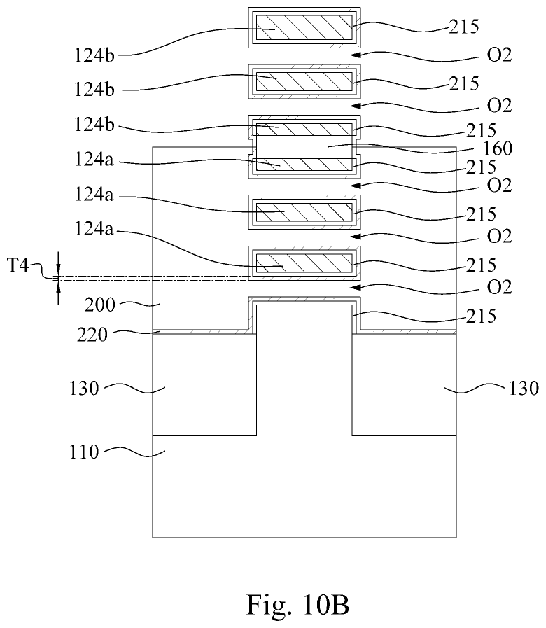

Reference is made to FIGS. 10A and 10B. Next, one or more doping loops (e.g., the doping loop illustrated in FIGS. 10A-12B may be performed one or more times) may be performed to dope one or more dipole dopant materials into the oxynitride layers 215. The dipole dopant materials may create differentials in the electrical potential of gate structures and thus may affect the threshold voltages Vt of the gate structures.

A first dipole layer 220 is formed (e.g., conformally) to surround the oxynitride layers 215 in the channel regions CH in accordance with some embodiments. The first dipole layer 220 may be an oxide or a nitride of a first dipole dopant. In some embodiments in which the epitaxial layers 124a are for forming n-type devices (e.g., NMOS transistors), the first dipole layer 220 may include TiO₂, Al₂O₃, AlN, Ga₂O₃, In₂O₃, Nb₂O₅, ZnO₂, or the like, and the first dipole layer 220 may include a p-type dipole dopant, such as but not limited to Ti, Al, Ga, In, Nb, Zn, or an element having a weaker oxygen attraction than Si, or the like. The dipole dopant material doped in a gate dielectric layer (e.g., the oxynitride layers 215 in this case) may form dipole moments with the material of the epitaxial layers 124a, thereby creating differentials in the electrical potential of the overall gate structure, and thus the threshold voltage Vt of the gate structure may be adjusted. The p-type dipole dopant may increase the threshold voltage Vt of a gate structure (for either an NMOS device or a PMOS device). The first dipole layer 220 may be formed by any suitable deposition methods such as ALD or CVD. A thickness T4 of the first dipole layer 220 may be in a range from about 0.1 nm to about 10 nm.

A dummy material 200 is filled in the gate trench GT1 and then etched back to a level substantially the same as the middle dielectric isolators 160. In some embodiments, the dummy material 200 may be a SiOx layer deposited using flowable chemical vapor deposition (FCVD), spin-on coating, or the like. The dummy material 200 are then planarized, and the dummy material 200 are recessed or etched back, so that portions of the first dipole layer 220 wrapping the epitaxial layers 124b are exposed.

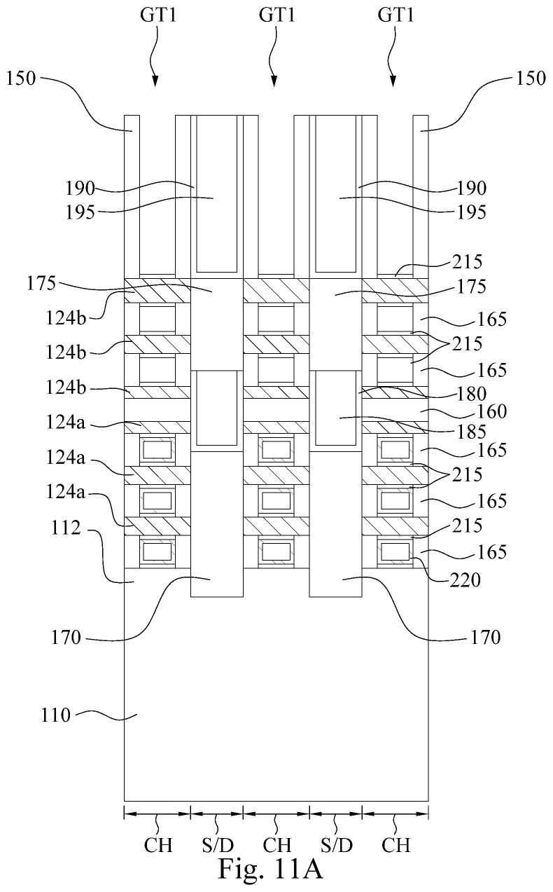

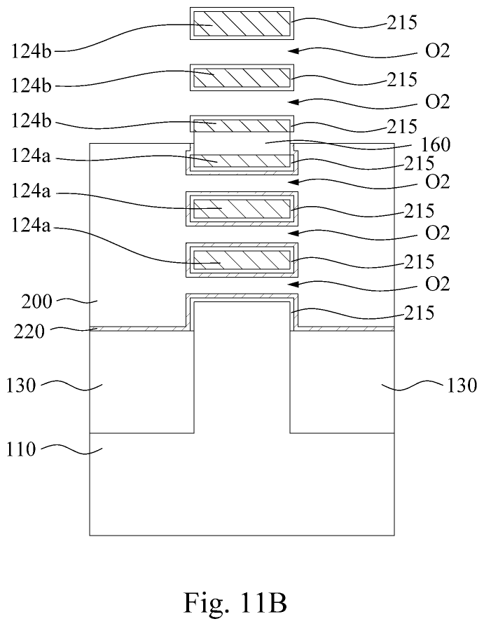

Reference is made to FIGS. 11A and 11B. Subsequently, the portions of the first dipole layer 220 wrapping around the epitaxial layers 124b are removed to expose the oxynitride layers 215 wrapping around the epitaxial layers 124b. A suitable etching process, such as a wet etch, may be performed to remove the first dipole layer 220 exposed by the dummy material 200, while the dummy material 200 shields (e.g., protects) the portions of the first dipole layer 220 wrapping around the epitaxial layers 124a from the etching process.

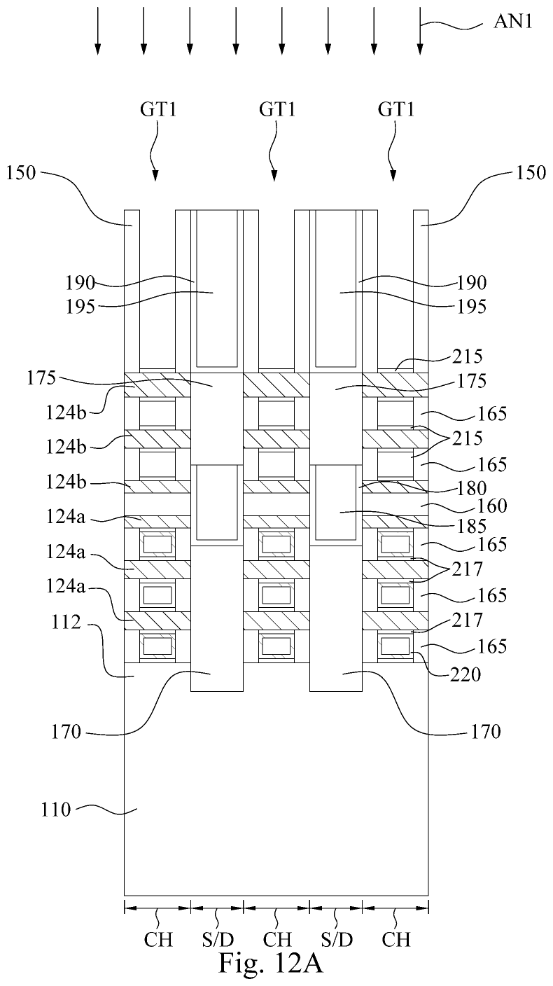

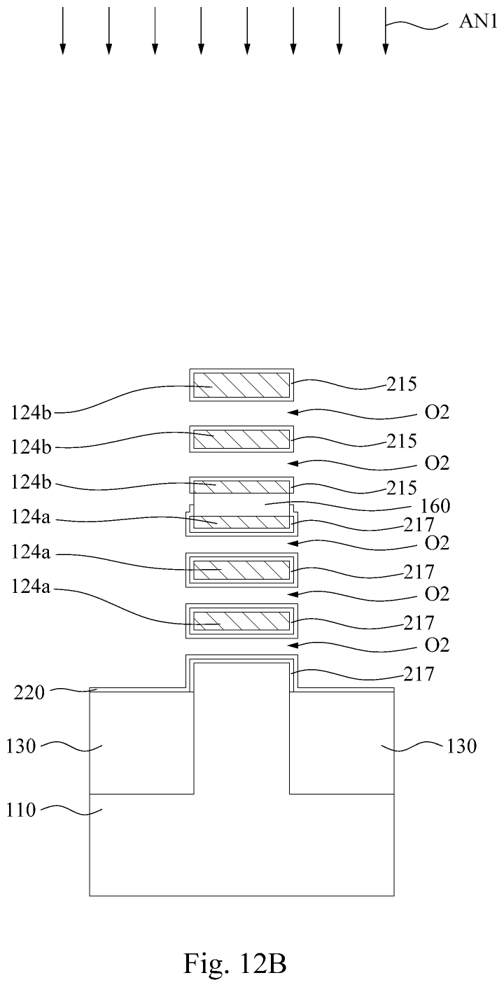

Reference is made to FIGS. 12A and 12B. The dummy material 200 (see FIG. 11B) is removed. Subsequently, a first anneal process AN1 is performed to diffuse the first dipole dopants in the first dipole layer 220 into the corresponding oxynitride layers 215, thereby forming first doped interfacial layers 217 in accordance with some embodiments. In some embodiments, the first anneal process AN1 is a soak anneal. The soak anneal may include applying a fixed temperature of about 150° C. to about 1050° C. for about 5 seconds to about 600 seconds in an ambient environment of N₂, NH₃, O₂, N₂O, or combinations thereof. In some embodiments, the first anneal process AN1 may be a spike anneal. The spike anneal may include applying a fixed temperature of about 150° C. to about 850° C. for about 5 seconds to about 120 seconds and rapidly raising the temperature to a peak temperature of about 1050° C. and sustaining the peak temperature in a short period, such as about 0.5 seconds to about 5 seconds, after which the temperature is rapidly reduced.

The first dipole dopants are dispersed in the first doped interfacial layers 217. The oxynitride layers 215 (and thus the first doped interfacial layers 217) block the first dipole dopants from diffusing into the epitaxial layers 124a. The first dipole dopants are mostly distributed at the interfaces between the first doped interfacial layers 217 and the epitaxial layers 124a. In some embodiments, if the first dipole dopants are diffused into the epitaxial layers 124a, the mobility at small electrical thickness at inversion state Tᵢₙᵥ of the integrated circuit structure 100a (see FIGS. 16A and 16B) may be dropped. However, since the oxynitride layers 215 block the first dipole dopants from diffusing into the epitaxial layers 124a, the mobility performance of the integrated circuit structure 100a can be improved. Also, the gate leakage J_{g} reduction issues and positive bias temperature instabilities (PBTI) of the integrated circuit structure 100a are improved as well.

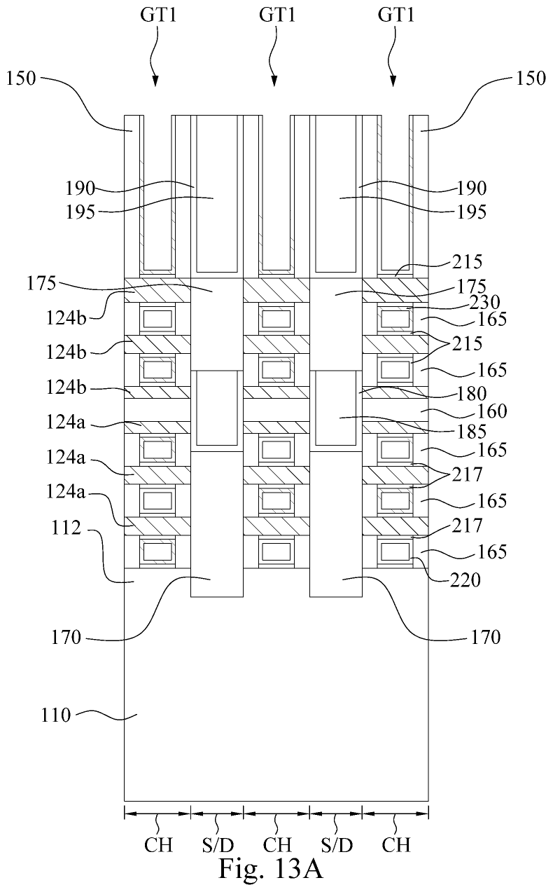

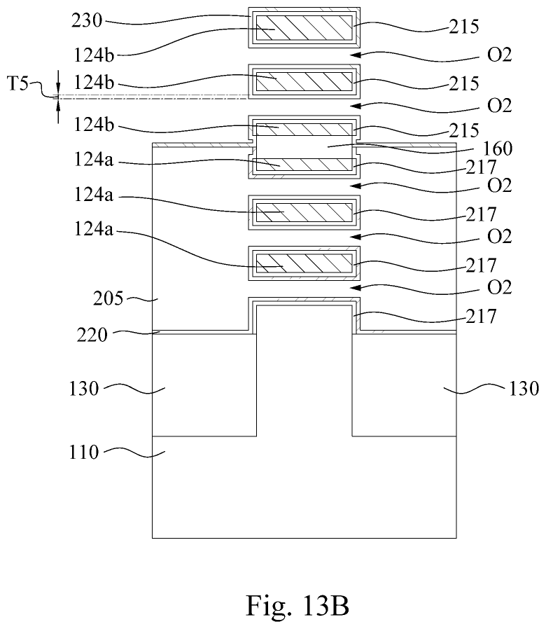

Reference is made to FIGS. 13A and 13B. Another dummy material 205 is formed in the gate trench GT1 and then etched back to a level substantially the same as the middle dielectric isolators 160. The dummy material 205 is similar to the dummy material 200 shown in FIGS. 10A-10B. Subsequently, a second dipole layer 230 is formed (e.g., conformally) to wrap around the epitaxial layers 124b. The second dipole layer 230 may be an oxide or a nitride of second dipole dopants. The second dipole dopants may be different from the first dipole dopants. For example, the second dipole dopants may be a dipole dopant having a different type from that of the first dipole dopants, such as an n-type dipole dopant, though the second dipole dopants may have a same type as the first dipole dopants. In some embodiments in which the epitaxial layers 124b are for forming p-type devices (e.g., PMOS transistors), the second dipole layer 230 may include La₂O₃, MgO, SrO, Y₂O₃, or the like, and the second dipole dopant in the second dipole layer 230 may be an n-type dipole dopant material such as La, Mg, Sr, Y, an element having a stronger oxygen attraction than Si, or the like. The n-type dipole dopant may decrease the threshold voltage Vt of a gate structure (for either an NMOS device or a PMOS device). The second dipole layer 230 may be formed by any suitable deposition methods such as ALD or CVD. A thickness T5 of the second dipole layer 230 may be in a range from about 0.1 nm to about 10 nm.

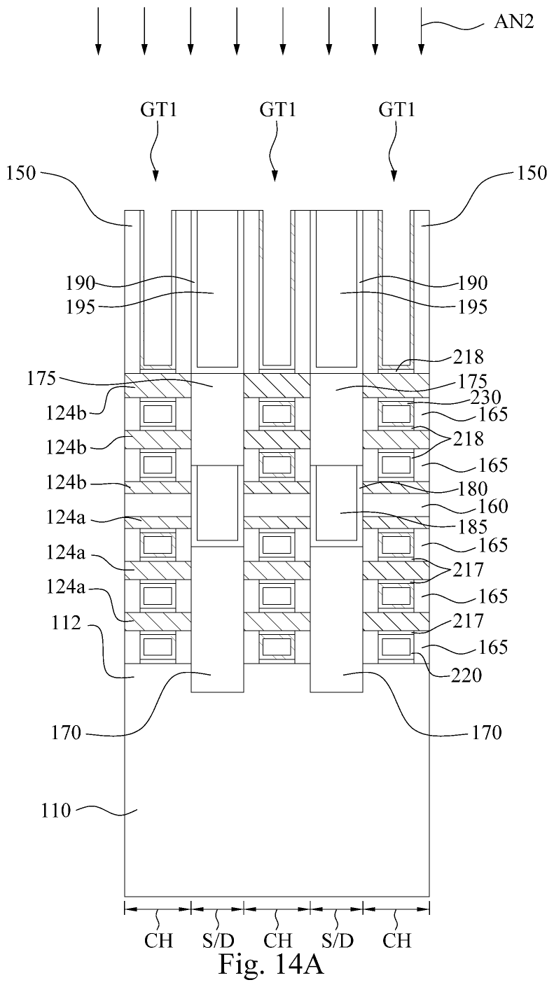

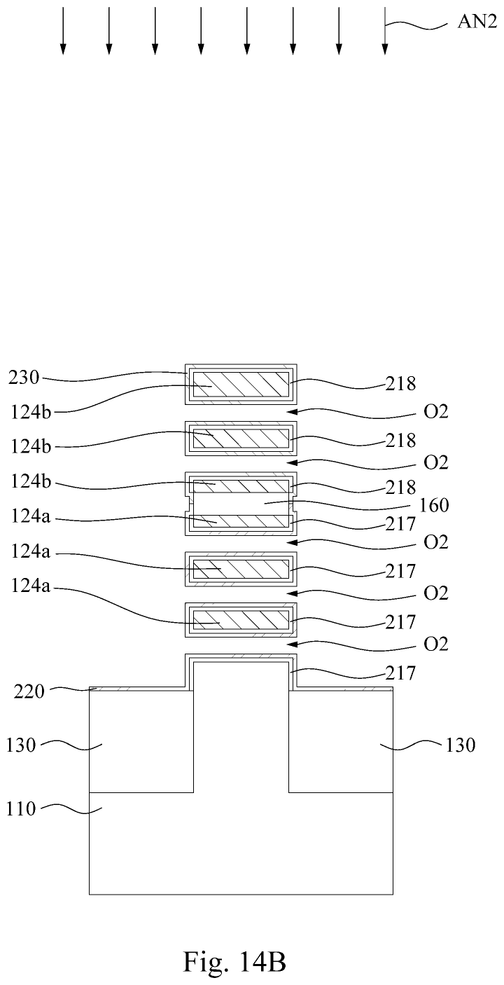

Reference is made to FIGS. 14A and 14B. The dummy material 205 (see FIG. 13B) is removed. A second anneal process AN2 is then performed to diffuse the second dipole dopants in the second dipole layer 230 into the corresponding oxynitride layers 215, thereby forming second doped interfacial layers 218 in accordance with some embodiments. In some embodiments, the second anneal process AN2 is similar to the first anneal process AN1.

The second dipole dopants are dispersed in the second doped interfacial layers 218. The oxynitride layers 215 (and thus the second doped interfacial layers 218) block the second dipole dopants from diffusing into the epitaxial layers 124b. The second dipole dopants are mostly distributed at the interfaces between the second doped interfacial layers 218 and the epitaxial layers 124b. Since the oxynitride layers 215 block the first dipole dopants from diffusing into the epitaxial layers 124b, mobility performance of the integrated circuit structure 100a can be improved. Also, the gate leakage J_{g} reduction issues and positive bias temperature instabilities (PBTI) of the integrated circuit structure 100a are improved as well.

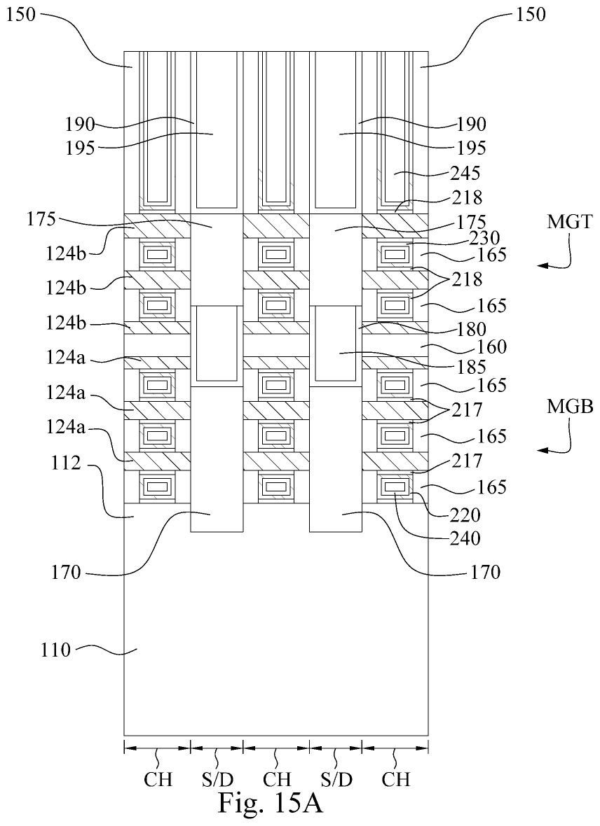

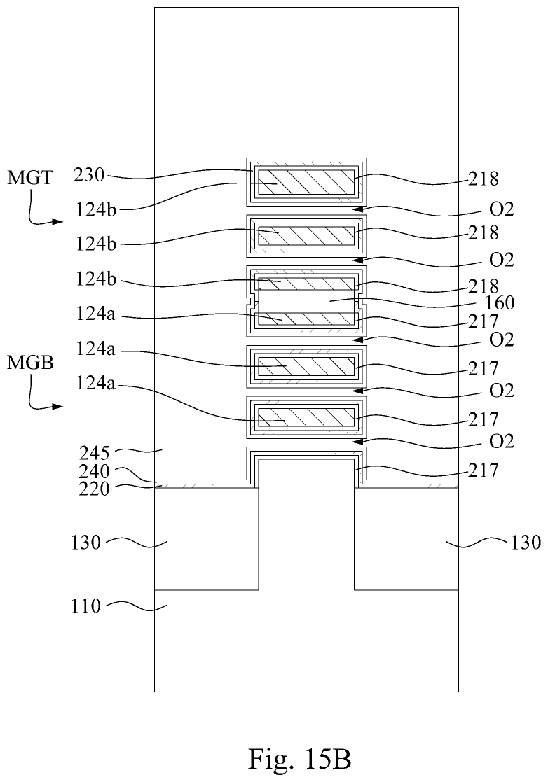

Reference is made to FIGS. 15A and 15B. A high-k gate dielectric layer 240 is formed over the first dipole layer 220 and the second dipole layer 230. High-k gate dielectrics include dielectric materials having a high dielectric constant, for example, greater than that of thermal silicon oxide (˜3.9). The high-k gate dielectric layer 240 may include hafnium oxide (HfO₂). Alternatively, the high-k gate dielectric layer 240 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

A work function metal material 245 is then formed to fill the gate trenches GT1. The work function metal material 245 may exemplarily include, but are not limited to, tungsten, platinum, aluminum, copper, nickel, cobalt, silver, gold, ruthenium, titanium, tantalum, titanium nitride, tantalum nitride, tungsten nitride, ruthenium oxide, nickel silicide, cobalt silicide, TaC, TaSiN, TaCN, TiAl, TiAlN, or other suitable materials. Therefore, the first doped interfacial layers 217, the first dipole layers 220, the high-k gate dielectric layers 240, and the work function metal material 245 form a gate structure MGB, and the second doped interfacial layers 218, the second dipole layers 230, the high-k gate dielectric layers 240, and the work function metal material 245 form a gate structure MGT.

Reference is made to FIGS. 16A and 16B. After the formation of the gate structures MGB and MGT as shown in FIGS. 15A and 15B, an etching back process is optionally performed to etch back the gate structures MGB and MGT, resulting in recesses over the etched-back gate structures MGB and MGT. In some embodiments, because the materials of the gate structures MGB and MGT have a different etch selectivity than the gate spacers 150, a selective etching process may be performed to etch back the gate structures MGB and MGT to lower the gate structures MGB and MGT. As a result, the top surface of the gate structures MGB and MGT may be at a lower level than the top surfaces of the gate spacers 150.

Subsequently, a dielectric cap layer is deposited over the substrate 110 until the recesses are overfilled. The dielectric cap layer includes SiNₓ, AlₓO_{y}, AlON, SiOₓC_{y}, SiCₓN_{y}, boron nitride (BN), boron carbonitride (BNC), combinations thereof or the like, and is formed by a suitable deposition technique such as CVD, plasma-enhanced CVD (PECVD), ALD, remote plasma ALD (RPALD), plasma-enhanced ALD (PEALD), combinations thereof or the like. A CMP process is then performed to remove the cap layer outside the recess, leaving portions of the dielectric cap layer in the recesses to serve as dielectric caps 248. The dielectric caps 248 are in direct contact with the gate structures MGB and MGT as shown in FIGS. 16A and 16B.

Source/drain contacts 250 are then formed in the second ILD layer 195 (see FIGS. 15A and 15B). For example, the second ILD layer 195 and the second CESL 190 are patterned to form openings therein, and conductive materials are then filled in the openings to form the source/drain contacts 250. As such, the source/drain contacts 250 are electrically connected to the second source/drain epitaxial structures 175.

In some embodiments, prior to filling the conductive materials in the openings, metal alloy layers 255 are respectively formed above the second source/drain epitaxial structures 175. The metal alloy layers 255, which may be silicide layers, are respectively formed in the trenches and over the exposed second source/drain epitaxial structures 175 by a self-aligned silicide (salicide) process.

As such, integrated circuit structure 100a is formed. As shown in FIGS. 16A and 16B, the integrated circuit structure 100a includes at least one bottom transistor Tb and at least one top transistor Tt. The top transistor Tt is over the bottom transistor Tb. The bottom transistor Tb includes the channel layers 124a, the first source/drain epitaxial structures 170 on opposite sides of the channel layers 124a and connected to the channel layers 124a, and the gate structure MGB wrapping around the channel layers 124a. The top transistor Tt includes the channel layers 124b, the second source/drain epitaxial structures 175 on opposite sides of the channel layers 124b and connected to the channel layers 124b, and the gate structure MGT wrapping around the channel layers 124b. The bottom transistor Tb is an N-type transistor, and the top transistor Tt is a P-type transistor, or vice versa.

The gate structure MGB includes the first doped interfacial layers 217, the first dipole layers 220, the high-k gate dielectric layers 240, and the work function metal materials 245. The first doped interfacial layers 217 are in contact with the channel layers 124a. The first dipole layers 220 are in contact with the first doped interfacial layers 217 and the high-k gate dielectric layers 240. The first doped interfacial layers 217 and the first dipole layers 220 include the same dipole dopants. The gate structure MGT includes the second doped interfacial layers 218, the second dipole layers 230, the high-k gate dielectric layers 240, and the work function metal materials 245. The second doped interfacial layers 218 are in contact with the channel layers 124b. The second dipole layers 230 are in contact with the second doped interfacial layers 218 and the high-k gate dielectric layers 240. The second doped interfacial layers 218 and the second dipole layers 230 include the same dipole dopants.

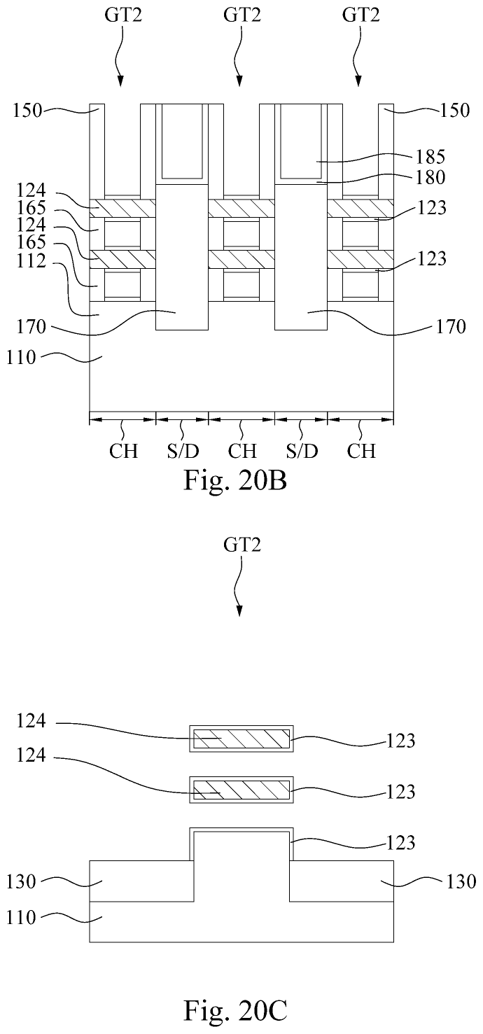

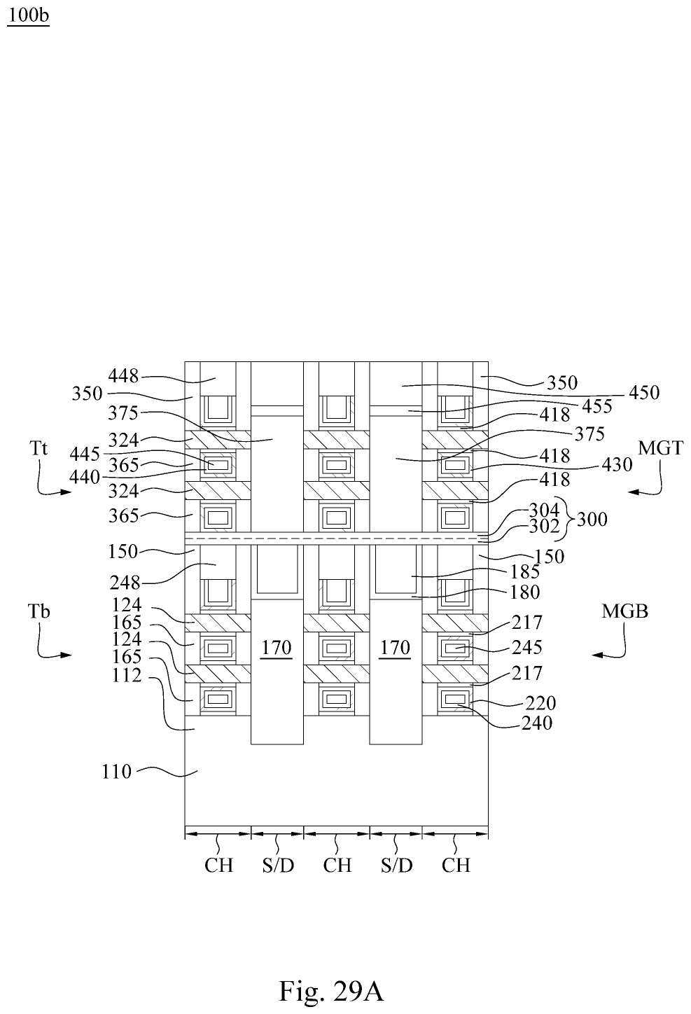

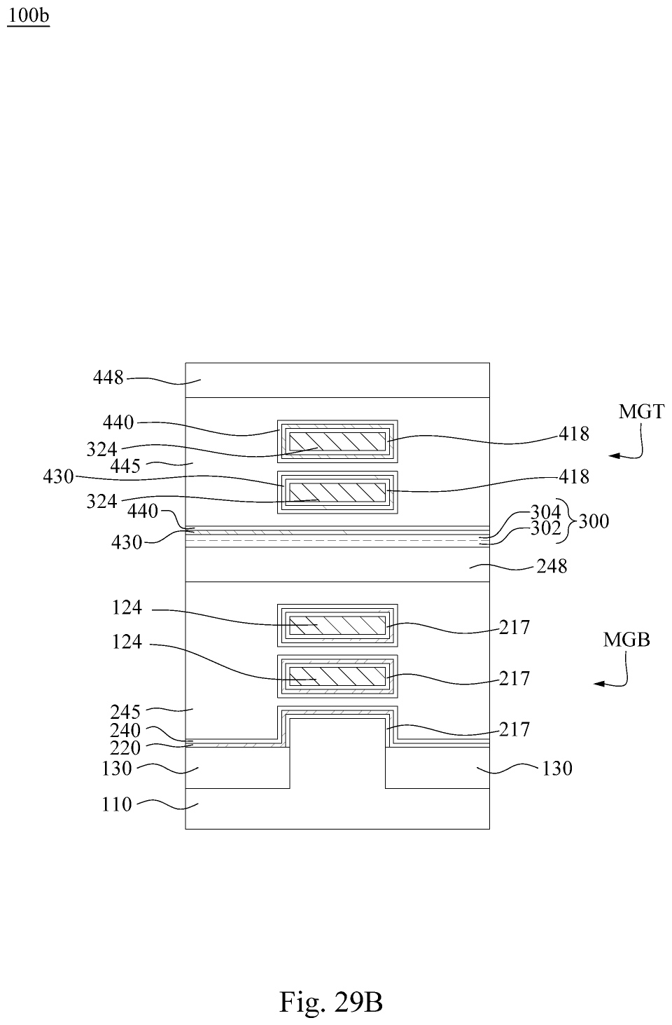

FIGS. 17-29B illustrate perspective views and cross-sectional views of intermediate stages in the formation of an integrated circuit structure (or a semiconductor device) 100b in accordance with some embodiments of the present disclosure. In some embodiments, the semiconductor device in FIGS. 29A and 29B is a CFET device. In addition to the integrated circuit structure 100b, FIGS. 17-20A depict X-axis, Y-axis, and Z-axis directions. FIGS. 20B, 21A, 22A, 23A, 24A, 25A, 26A, 27A, 28A, and 29A are cross-sectional views of some embodiments of the integrated circuit structure 100b at intermediate stages along a first cut (e.g., cut I-I in FIG. 20A). FIGS. 20C, 21B, 22B, 23B, 24B, 25B, 26B, 27B, 28B, and 29B are cross-sectional views of some embodiments of the integrated circuit structure 100b at intermediate stages along a second cut (e.g., cut II-II in FIG. 20A). The formed devices include a p-type transistor (such as a p-type GAA FET) and an n-type transistor (such as an n-type GAA FET) in accordance with some exemplary embodiments. Throughout the various views and illustrative embodiments, like reference numbers are used to designate like elements. It is understood that additional operations can be provided before, during, and after the processes shown by FIGS. 17-29B, and some of the operations described below can be replaced or eliminated, for additional embodiments of the method. The order of the operations/processes may be interchangeable.

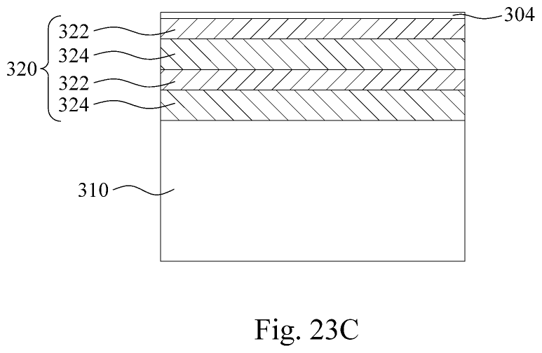

Reference is made to FIG. 17. An epitaxial stack 120 is formed over a substrate 110. The substrate 110 in FIG. 17 is the same as or similar to the substrate 110 in FIG. 1. The epitaxial stack 120 includes epitaxial layers 122 of a first composition interposed by epitaxial layers 124 of a second composition. The epitaxial layers 122 in FIG. 17 are the same as or similar to the epitaxial layers 122a in FIG. 1, and the epitaxial layers 124 in FIG. 17 are the same as or similar to the epitaxial layers 124a in FIG. 1. The epitaxial layers 124 or portions thereof may form nanostructure channel(s) of the nanostructure transistor (e.g., the bottom transistor Tb in FIG. 23A).

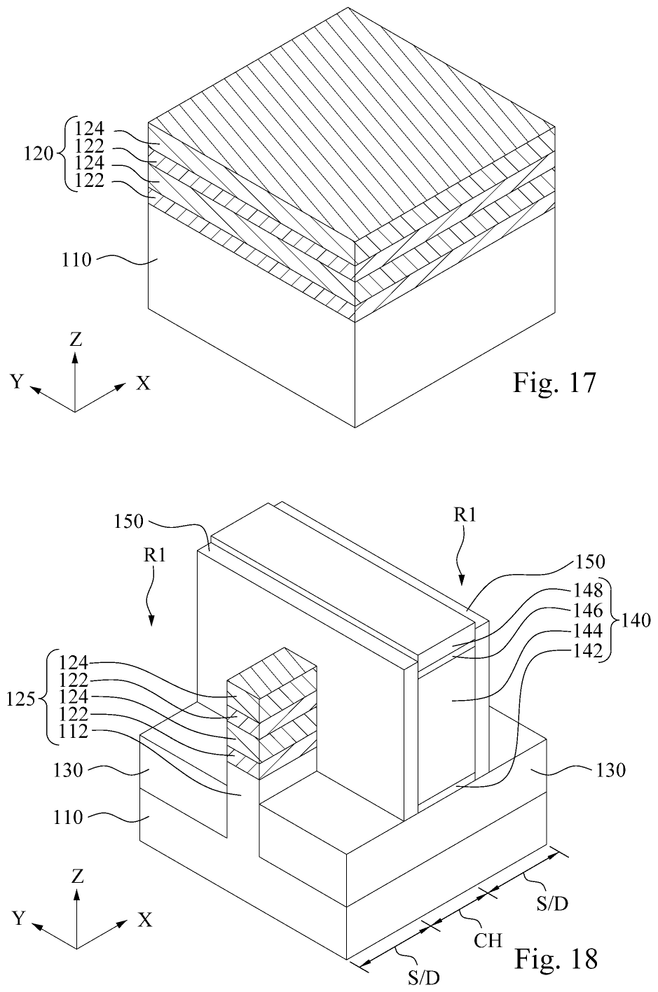

Reference is made to FIG. 18. At least one fin structure 125 extending from the substrate 110 is formed. In various embodiments, the fin structure 125 includes a protruding portion 112 formed from the substrate 110 and portions of each of the epitaxial layers of the epitaxial stack 120 including epitaxial layers 122 and 124. Next, isolation structures 130 are formed to surround the fin structure 125. The isolation structures 130 in FIG. 18 are the same as or similar to the isolation structures 130 in FIG. 2.

At least one dummy gate structure 140 is formed over the substrate 110 and is partially disposed over the fin structure 125. The dummy gate structure 140 in FIG. 18 is the same as or similar to the dummy gate structure 140 in FIG. 2. For example, the dummy gate structure 140 includes a dummy gate dielectric layer 142, a dummy gate electrode layer 144, and a hard mask (e.g., a nitride layer 146 and an oxide layer 148). The portion of the fin structure 125 underlying the dummy gate structure 140 may be referred to as the channel region CH. The dummy gate structure 140 may also define source/drain regions S/D of the fin structure 125, for example, the regions of the fin structure 125 adjacent and on opposite sides of the channel region CH. After formation of the dummy gate structure 140 is completed, gate spacers 150 are formed on sidewalls of the dummy gate structure 140. The gate spacers 150 in FIG. 18 are the same as or similar to the gate spacers 150 in FIG. 2.

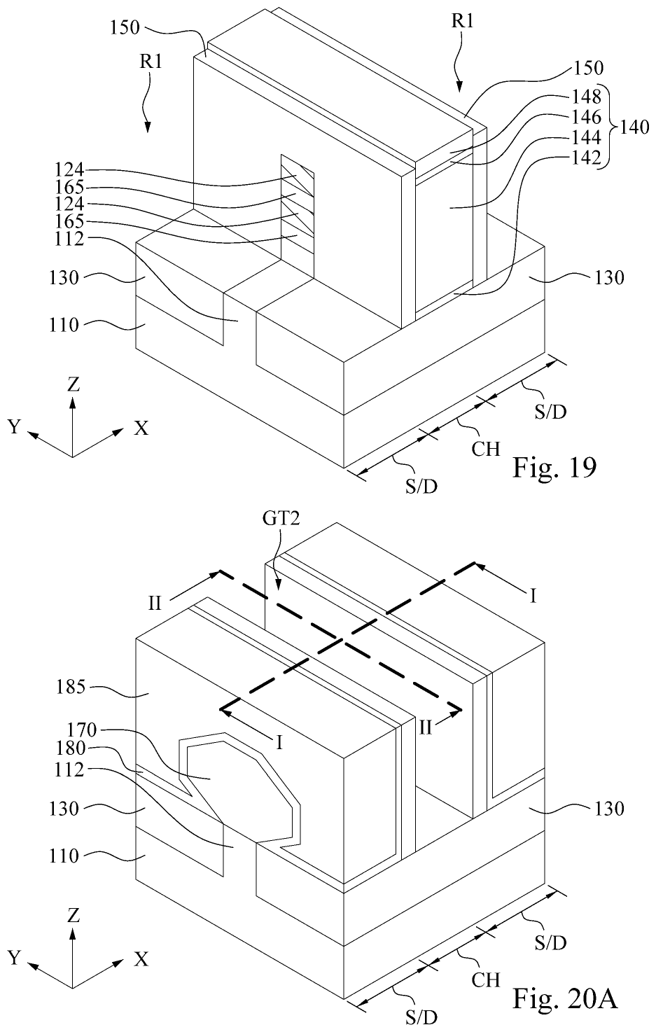

Reference is made to FIG. 19. Exposed portions of the fin structure 125 that extend laterally beyond the gate spacers 150 (e.g., in source/drain regions S/D of the fin structure 125) are etched by using, for example, an anisotropic etching process that uses the dummy gate structure 140 and the gate spacers 150 as an etch mask, resulting in recesses into the fin structure 125. Subsequently, the epitaxial layers 122 (see FIG. 18) are laterally or horizontally recessed, and inner dielectric spacers 165 are filled in the recesses, respectively. The inner dielectric spacers 165 in FIG. 19 are the same as or similar to the inner dielectric spacers 165 in FIGS. 5A and 5B.

Reference is made to FIGS. 20A-20C. First source/drain epitaxial structures 170 are formed over the source/drain regions S/D of the fin structure 125. The first source/drain epitaxial structures 170 in FIGS. 20A and 20B are the same as or similar to the first source/drain epitaxial structures 170 in FIGS. 5A and 5B. A first ILD layer 185 is then formed on the substrate 110. In some embodiments, a first CESL 180 is also formed prior to forming the first ILD layer 185. The first ILD layer 185 in FIGS. 20A and 20B is the same as or similar to the first ILD layer 185 in FIG. 5A, and the first CESL 180 in FIGS. 20A and 20B is the same as or similar to the first CESL 180 in FIG. 5A. After the formation of the first ILD layer 185, the hard mask layers 146 and 148 (as shown in FIG. 19) are removed to expose the dummy gate electrode layer 144.

Thereafter, the dummy gate electrode layer 144 and the dummy gate dielectric layer 142 in FIG. 19 are removed first, and then the epitaxial layers (i.e., sacrificial layers) 122 in FIG. 18 are removed, thus resulting in gate trenches GT2 between the gate spacers 150. After the removal of the epitaxial layers 122, native oxide layers 123 are grown on the exposed surfaces of the epitaxial layers 124. Further, similar to the native oxide layers 123 shown in FIG. 6C, OH bonds exist on the exposed surfaces of the native oxide layers 123.

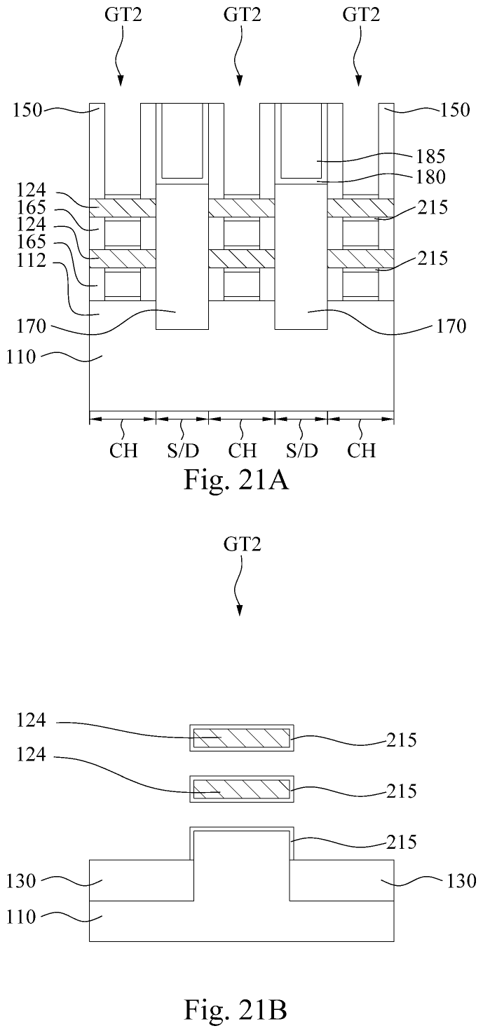

Reference is made to FIGS. 21A and 21B. After the formation of the gate trenches GT2, the structure of FIGS. 20B and 20C undergoes the processes similar to the processes shown in FIGS. 7A-9D. As such, oxynitride layers 215 are formed to surround the epitaxial layers 124. The fabrication process details about the formation of the oxynitride layers 215 are similar to that about the formation of the oxynitride layers 215 in FIGS. 7A-9D, and thus they are not repeated herein for the sake of brevity.

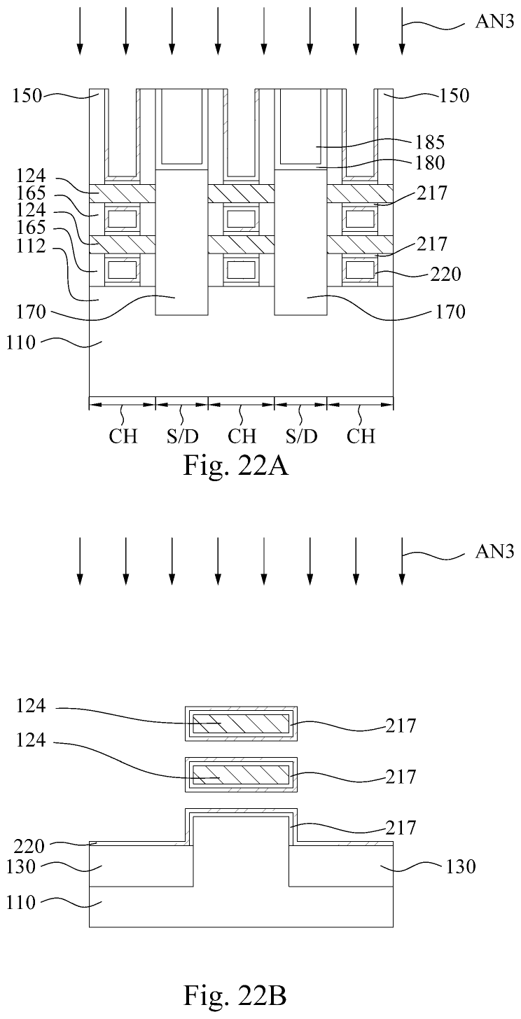

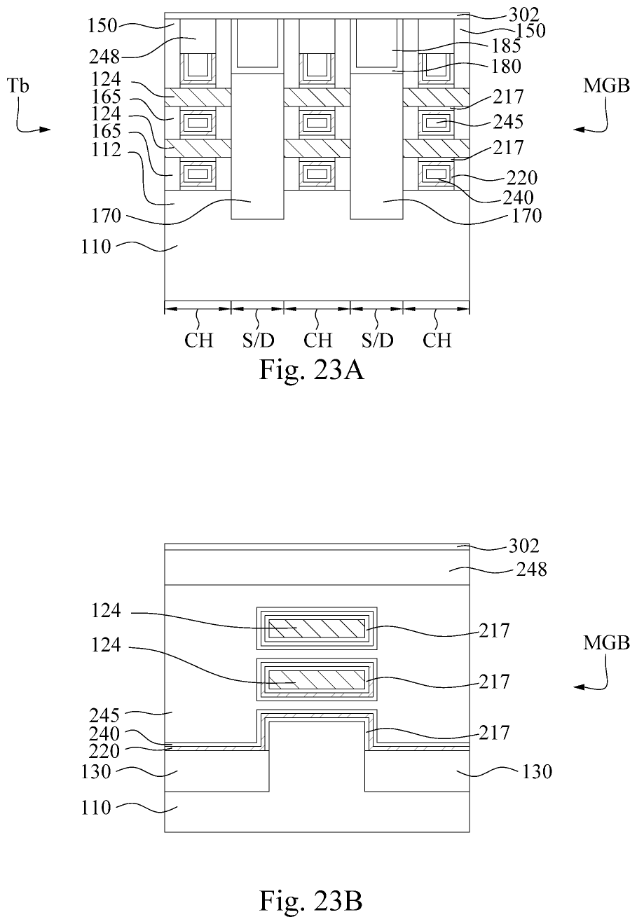

Reference is made to FIGS. 22A and 22B. A first dipole layer 220 is formed (e.g., conformally) over the oxynitride layers 215 in the channel regions CH in accordance with some embodiments. The first dipole layer 220 in FIGS. 22A and 22B are the same as or similar to the first dipole layer 220 in FIGS. 10A and 10B.

Subsequently, a first anneal process AN3 is performed to diffuse first dipole dopants in the first dipole layer 220 into the corresponding oxynitride layers 215, thereby forming first doped interfacial layers 217 in accordance with some embodiments. The fabrication process details about the first anneal process AN3 are similar to that about the first anneal process AN1 in FIGS. 12A and 12B, and thus they are not repeated herein for the sake of brevity.

Reference is made to FIGS. 23A and 23B. After the formation of the first doped interfacial layers 217, the structure of FIGS. 22A and 22B then undergoes the processes similar to the processes shown in FIGS. 15A and 15B to complete the formation of the gate structures MGB. Subsequently, the gate structures MGB may be etched back, and dielectric caps 248 may be formed over the etched-back gate structures MGB. The dielectric caps 248 in FIGS. 23A and 23B are the same as or similar to the dielectric caps 248 in FIGS. 16A and 16B. As such, the channel layers 124, the first source/drain epitaxial structures 170, and the gate structure MGB form a bottom transistor Tb.

A first bonding layer 302 is formed over the bottom transistor Tb. In some embodiments, the first bonding layer 302 is a dielectric material including silicon oxide or other suitable materials. The first bonding layer 302 may be formed by atomic layer deposition (ALD), chemical vapor deposition (CVD), and/or other suitable method.

Reference is made to FIG. 23C. Another substrate 310 is provided. In some embodiments, the substrate 310 in FIG. 23C is the same as or similar to the substrate 110 in FIG. 23A. Another epitaxial stack 320 is formed over the substrate 310. The epitaxial stack 320 includes epitaxial layers 322 of the first composition interposed by epitaxial layers 324 of the second composition. In some embodiments, the epitaxial layers 322 in FIG. 23C are the same as or similar to the epitaxial layers 122 in FIG. 17, and the epitaxial layers 324 in FIG. 23C is the same as or similar to the epitaxial layers 124 in FIG. 17. The epitaxial layers 324 or portions thereof may form nanostructure channel(s) of the nanostructure transistor (e.g., the top transistor Tt in FIGS. 29A and 29B). The epitaxial layers 322 may also be referred to as sacrificial layers.

A second bonding layer 304 is formed over the epitaxial stack 320. In some embodiments, the second bonding layer 304 is a dielectric material including silicon oxide or other suitable materials. The second bonding layer 304 may be formed by atomic layer deposition (ALD), chemical vapor deposition (CVD), and/or other suitable method.

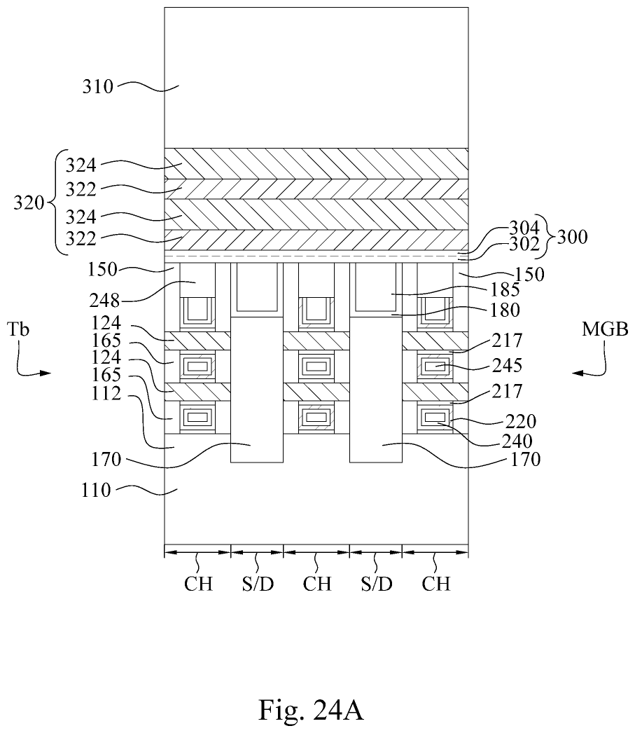

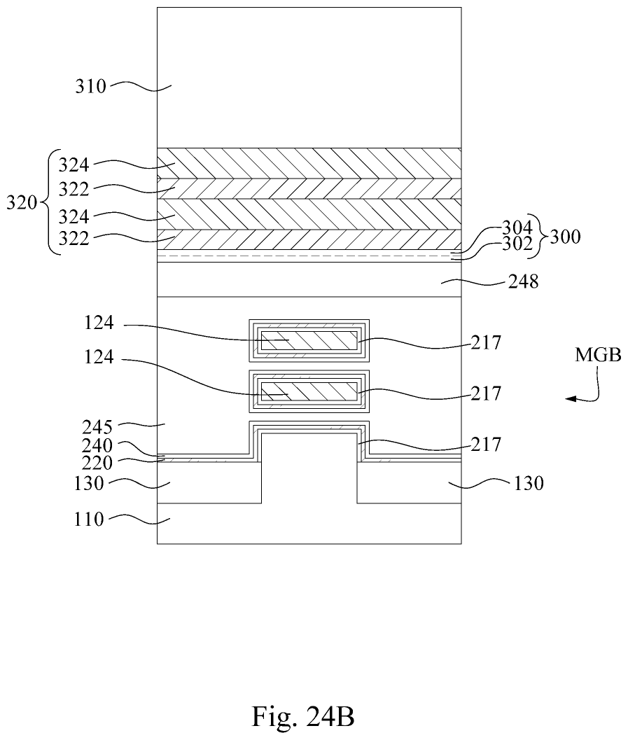

Reference is made to FIGS. 24A and 24B. The structure in FIG. 23C and the structure in FIGS. 23A and 23B are bonded at the surfaces on which the first and second bonding layers 302 and 304 are formed. The first and second bonding layers 302 and 304 are combined and become an insulator layer 300 bonding the bottom transistor Tb and the epitaxial stack 320. The insulator layer 300 is disposed between and bridges the bottom transistor Tb and the epitaxial stack 320.

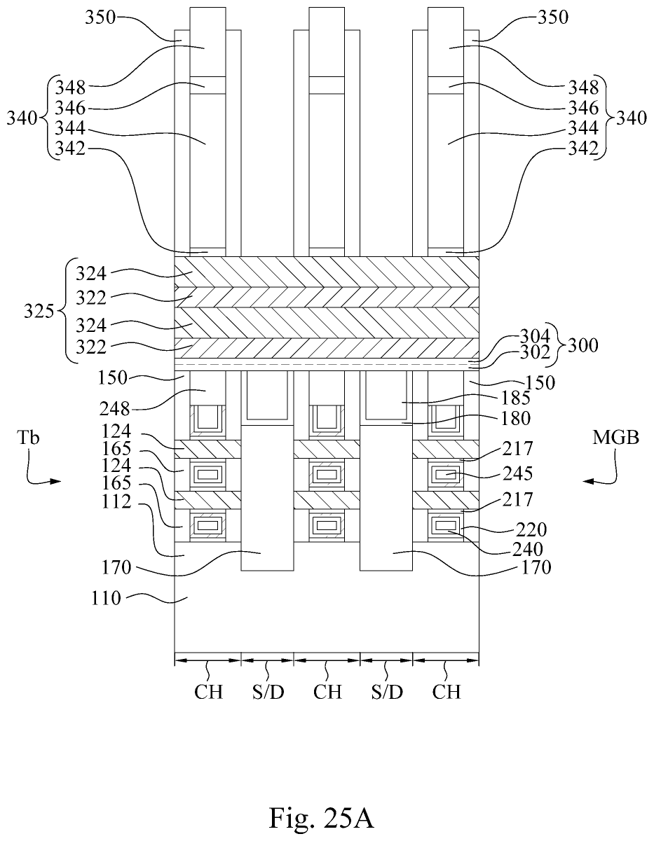

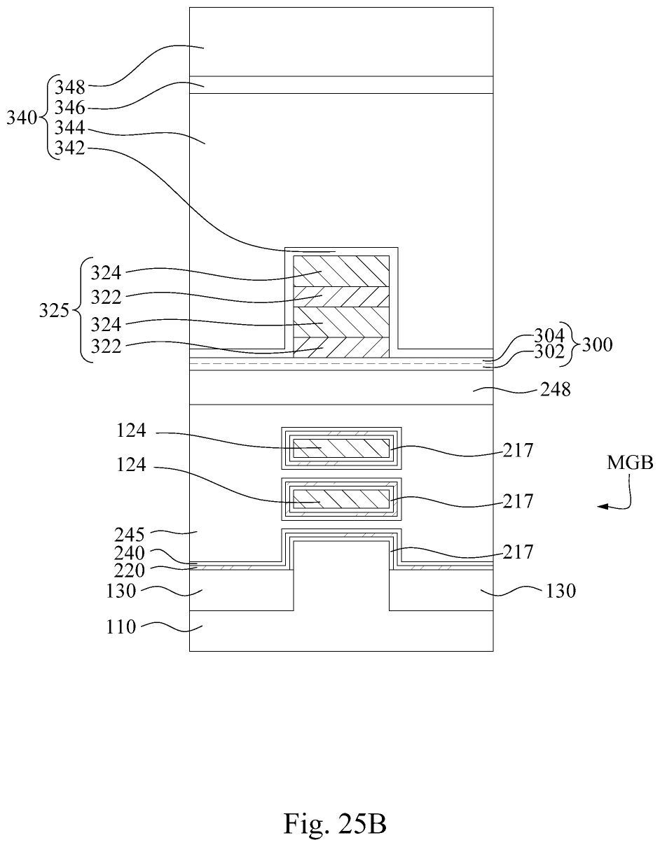

Reference is made to FIGS. 25A and 25B. The substrate 310 in FIGS. 24A and 24B is removed, such that the top surface of the epitaxial layer 324 is exposed. Subsequently, the epitaxial stack 320 is patterned to form at least one fin structure 325 extending from the insulator layer 300. In various embodiments, the fin structure 325 includes portions of each of the epitaxial layers of the epitaxial stack 320 including epitaxial layers 322 and 324.

At least one dummy gate structure 340 is formed over the insulator layer 300 and across the fin structure 325. The dummy gate structure 340 in FIGS. 25A and 25B is the same as or similar to the dummy gate structure 140 in FIG. 2. For example, the dummy gate structure 340 includes a gate dielectric layer 342, a dummy gate electrode layer 344, and a hard mask (e.g., a nitride layer 346 and an oxide layer 348). After formation of the dummy gate structure 340 is completed, gate spacers 350 are formed on sidewalls of the dummy gate structure 340. The gate spacers 350 in FIGS. 25A and 25B are the same as or similar to the gate spacers 150 in FIG. 2. The dummy gate structure 340 may also define source/drain regions S/D of the fin structure 325, for example, the regions of the fin structure 325 adjacent and on opposing sides of the channel region CH.

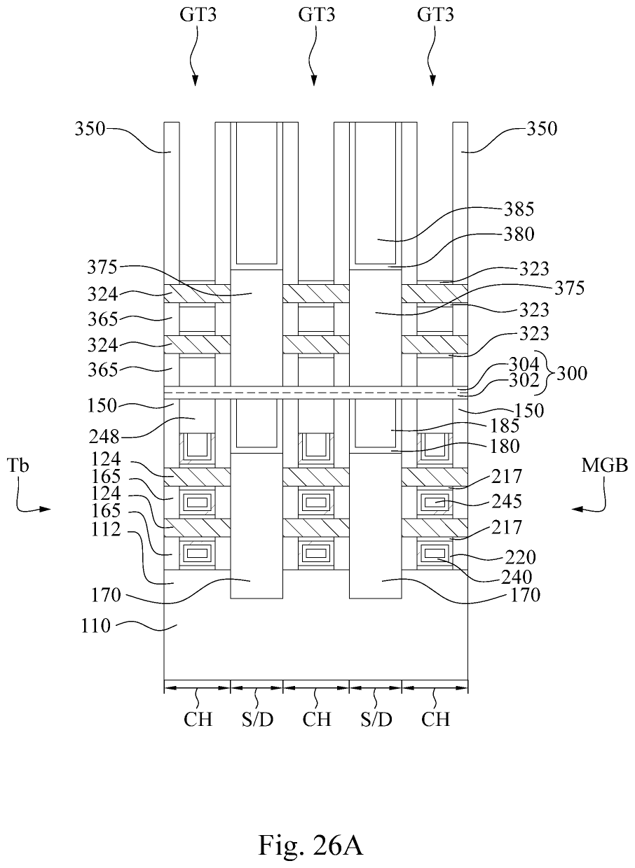

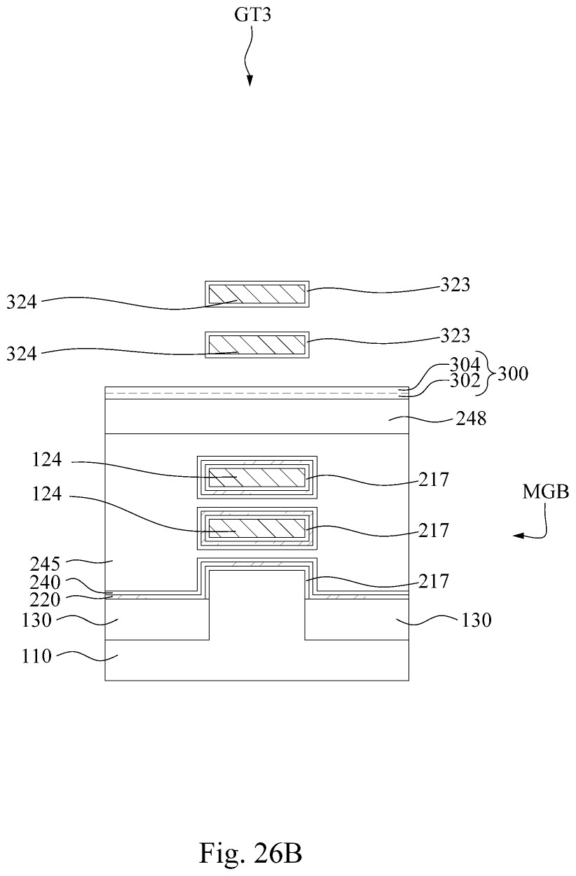

Reference is made to FIGS. 26A and 26B. Exposed portions of the fin structure 325 that extend laterally beyond the gate spacers 350 (e.g., in source/drain regions S/D of the fin structure 325) are etched by using, for example, an anisotropic etching process that uses the dummy gate structure 340 and the gate spacers 350 as an etch mask, resulting in recesses into the fin structure 325. Subsequently, the epitaxial layers 322 (see FIGS. 25A and 25B) are laterally or horizontally recessed, and inner dielectric spacers 365 are filled in the recesses, respectively. The inner dielectric spacers 365 in FIGS. 26A and 26B are the same as or similar to the inner dielectric spacers 165 in FIGS. 5A and 5B.

Second source/drain epitaxial structures 375 are formed over the source/drain regions S/D of the fin structure 325 and the bottom transistor Tb. The second source/drain epitaxial structures 375 in FIGS. 26A and 26B are the same as or similar to the second source/drain epitaxial structures 175 in FIGS. 5A and 5B. A second ILD layer 385 is then formed on the substrate 110. In some embodiments, a second CESL 380 is also formed prior to forming the second ILD layer 385. The second ILD layer 385 in FIGS. 26A and 26B is the same as or similar to the first ILD layer 185 in FIG. 5A, and the second CESL 380 in FIGS. 26A and 26B is the same as or similar to the first CESL 180 in FIG. 5A. After the formation of the second ILD layer 385, the hard mask layers 346 and 348 (as shown in FIGS. 25A and 25B) are removed to expose the dummy gate electrode layer 344.

Thereafter, the dummy gate electrode layer 344 and the gate dielectric layer 342 in FIGS. 25A and 25B are removed first, and then the epitaxial layers (i.e., sacrificial layers) 322 in FIGS. 25A and 25B are removed, thus resulting in gate trenches GT3 between the gate spacers 350. After the removal of the epitaxial layers 322, native oxide layers 323 are grown on the exposed surfaces of the epitaxial layers 324. Further, similar to the native oxide layers 123 shown in FIG. 6C, OH bonds exist on the exposed surfaces of the native oxide layers 323.

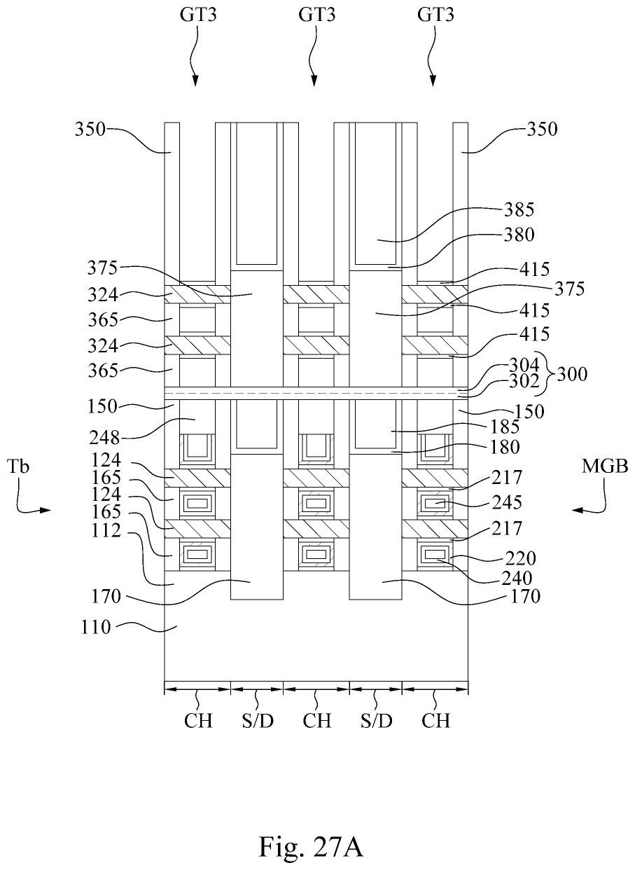

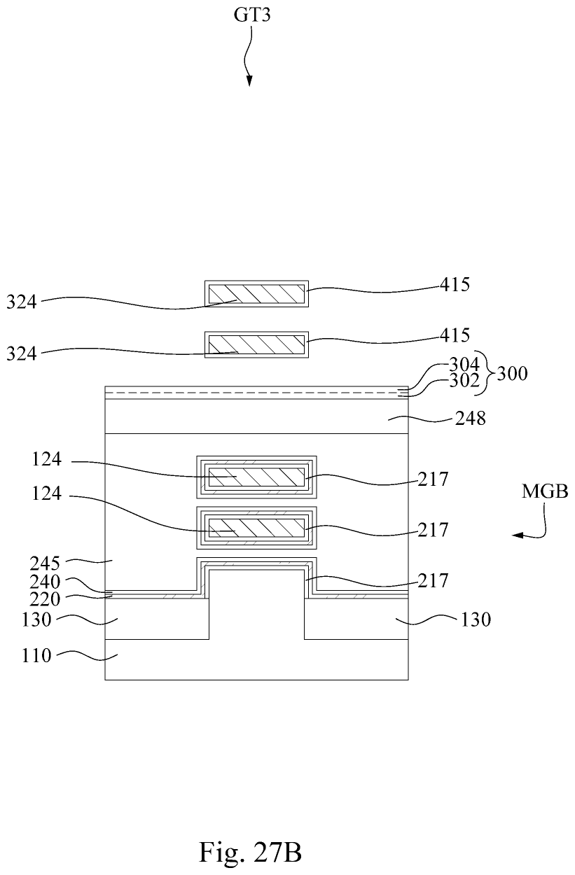

Reference is made to FIGS. 27A and 27B. After the formation of the gate trenches GT3, the structure of FIGS. 26A and 26B undergoes the processes similar to the processes shown in FIGS. 7A-9D. As such, oxynitride layers 415 are formed to surround the epitaxial layers 324. The fabrication process details about the formation of the oxynitride layers 415 are similar to that about the formation of the oxynitride layers 215 in FIGS. 7A-9D, and thus they are not repeated herein for the sake of brevity.

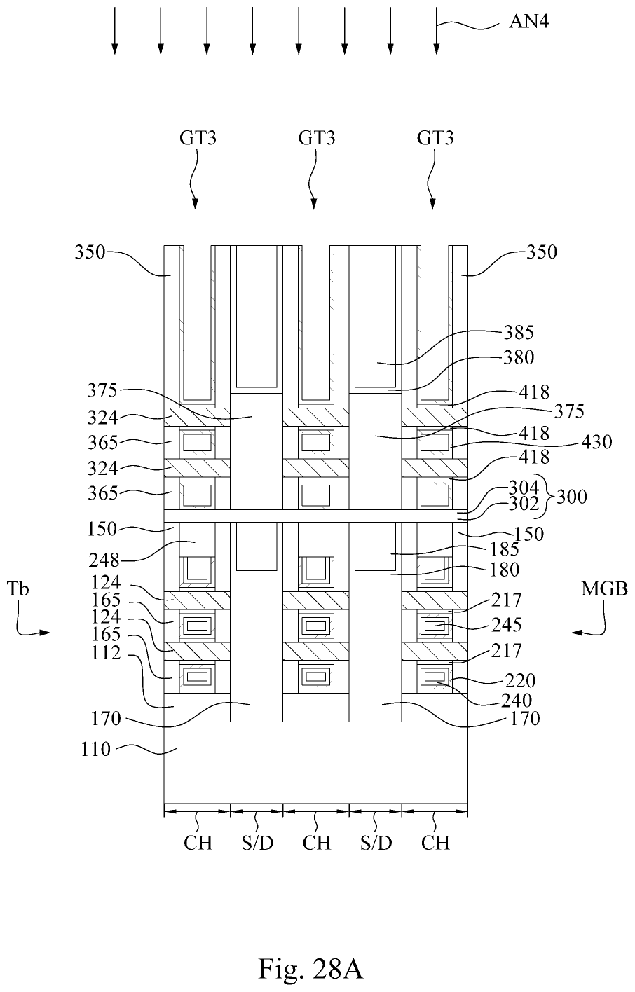

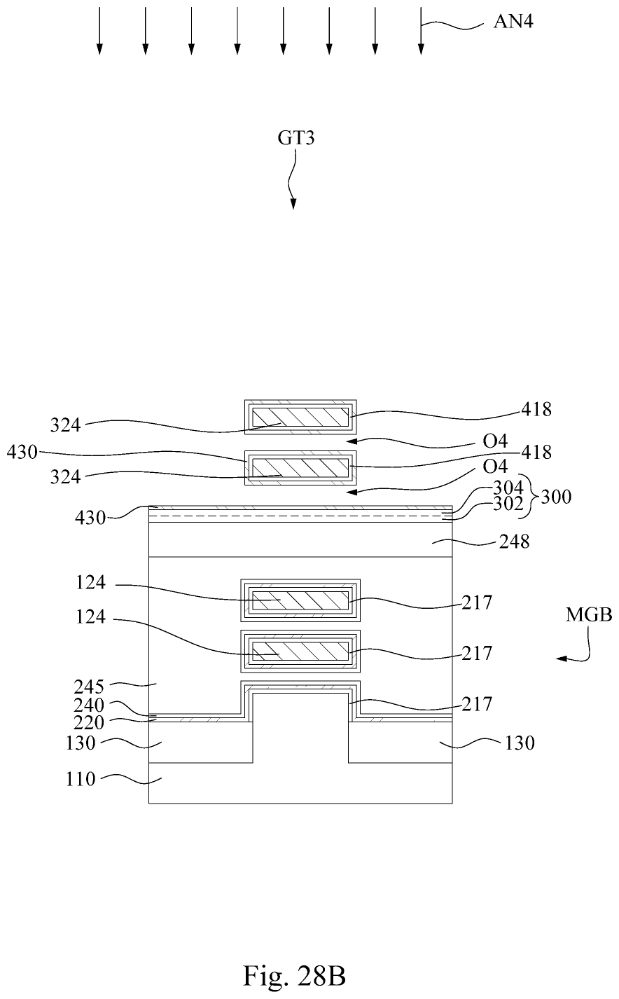

Reference is made to FIGS. 28A and 28B. A second dipole layer 430 is formed (e.g., conformally) to surround the oxynitride layers 415 in the channel regions CH in accordance with some embodiments. The second dipole layer 430 in FIGS. 28A and 28B are the same as or similar to the second dipole layer 230 in FIGS. 13A and 13B.

Subsequently, a second anneal process AN4 is performed to diffuse the first dipole dopants in the second dipole layer 430 into the corresponding oxynitride layers 415, thereby forming second doped interfacial layers 418 in accordance with some embodiments. The fabrication process details about the second anneal process AN4 are similar to that about the first anneal process AN1 in FIGS. 12A and 12B, and thus they are not repeated herein for the sake of brevity.

Reference is made to FIGS. 29A and 29B. After the formation of the second doped interfacial layers 218, the structure of FIGS. 28A and 28B undergoes the processes similar to the processes shown in FIGS. 15A-16B to complete the formation of the integrated circuit structure (or a semiconductor device) 100b. For example, gate structures MGT are formed. For example, high-k gate dielectric layers 440 and work function metal materials 445 are formed in the gate trenches GT3. The high-k gate dielectric layers 440 in FIGS. 29A and 29B are the same as or similar to the high-k gate dielectric layers 240 in FIGS. 15A and 15B, and the work function metal materials 445 in FIGS. 29A and 29B are the same as or similar to the work function metal materials 245 in FIGS. 15A and 15B.

Dielectric caps 448 are formed over the gate structures MGT, such that top transistors Tt are formed. Source/drain contacts 450 are then formed to be electrically connected to the second source/drain epitaxial structures 375, and metal alloy layers 255 are optionally formed over the second source/drain epitaxial structures 375 prior to the formation of the source/drain contacts 450. The source/drain contacts 450 in FIGS. 29A and 29B are the same as or similar to the source/drain contacts 250 in FIGS. 16A and 16B, and the metal alloy layers 455 in FIGS. 29A and 29B are the same as or similar to the metal alloy layers 255 in FIGS. 16A and 16B.

As such, integrated circuit structure 100b is formed. As shown in FIGS. 29A and 29B, the integrated circuit structure 100b includes at least one bottom transistor Tb, at least one top transistor Tt, and an insulator layer 300 between the bottom transistor Tb and the top transistor Tt. The top transistor Tt is over the bottom transistor Tb. The bottom transistor Tb includes the channel layers 124, the first source/drain epitaxial structures 170 on opposite sides of the channel layers 124 and connected to the channel layers 124, and the gate structure MGB surround the channel layers 124. The top transistor Tt includes the channel layers 324, the second source/drain epitaxial structures 375 on opposite sides of the channel layers 324 and connected to the channel layers 324, and the gate structure MGT surround the channel layers 324. The bottom transistor Tb is an N-type transistor, and the top transistor Tt is a P-type transistor, or vice versa.

The gate structure MGB includes the first doped interfacial layers 217, the first dipole layers 220, the high-k gate dielectric layers 240, and the work function metal materials 245. The first doped interfacial layers 217 are in contact with the channel layers 124. The first dipole layers 220 are in contact with the first doped interfacial layers 217 and the high-k gate dielectric layers 240. The first doped interfacial layers 217 and the first dipole layers 220 include the same dipole dopants. The gate structure MGT includes the second doped interfacial layers 418, the second dipole layers 430, the high-k gate dielectric layers 440, and the work function metal materials 445. The second doped interfacial layers 418 are in contact with the channel layers 324. The second dipole layers 430 are in contact with the second doped interfacial layers 418 and the high-k gate dielectric layers 440. The second doped interfacial layers 418 and the second dipole layers 430 include the same dipole dopants. Further, the second doped interfacial layers 418 are spaced apart from the insulator layer 300.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the oxynitride layers block the dipole dopants from diffusing into the channel layers, the mobility performance of the integrated circuit structure can be improved. Also, the gate leakage J_{g} reduction issues and positive bias temperature instabilities (PBTI) of the integrated circuit structure are improved as well. In addition, the oxynitride layers may be formed by using a microwave annealing process at low temperature to achieve low thermal budget for the bottom transistors.

According to some embodiments, a method includes forming a fin structure over a substrate, wherein the fin structure includes a first sacrificial layer, a first channel layer, a second sacrificial layer, and a second channel layer arranged in a stacking direction; forming a dummy gate structure across the fin structure; forming gate spacers on opposite sides of the dummy gate structure; forming first source/drain epitaxial layers on opposite sides of the first channel layer and spaced apart from the second channel layer; forming second source/drain epitaxial layers on opposite sides of the second channel layer and spaced apart from the first source/drain epitaxial layers; removing the dummy gate structure, the first sacrificial layer, and the second sacrificial layer to form a gate trench defined by the gate spacers; forming an oxynitride layer in the gate trench to surround the first channel layer; forming a dipole layer comprising dipole dopants in the gate trench to surround the oxynitride layer; performing an anneal process to drive the dipole dopants into the oxynitride layer; and after performing the anneal process, sequentially depositing a high-k gate dielectric layer and a work function metal layer in the gate trench to form a gate structure.

According to some embodiments, a method includes forming a bottom transistor over a substrate; forming a fin structure over the bottom transistor, wherein the fin structure includes a sacrificial layer and a channel layer over the sacrificial layer; forming a dummy gate structure across the fin structure; forming source/drain epitaxial layers on opposite sides of the channel layer and over the bottom transistor; removing the dummy gate structure and the sacrificial layer; forming a nitrogen-containing interfacial layer to surround the channel layer; depositing a dipole layer to surround the nitrogen-containing interfacial layer; performing an anneal process to drive dipole dopants into the nitrogen-containing interfacial layer; and forming a high-k gate dielectric layer and a work function metal layer to surround the nitrogen-containing interfacial layer to form a gate structure.

According to some embodiments, a device includes a bottom transistor and a top transistor over the bottom transistor. The bottom transistor includes a first channel layer, a first gate structure surrounding the first channel layer, and first source/drain epitaxial structures on opposite sides of the first channel layer. The first gate structure includes a first doped interfacial layer and a first work function metal layer. The first doped interfacial layer is in contact with the first channel layer and includes nitrogen and first dipole dopants. The first work function metal layer surrounds the first doped interfacial layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a fin structure over a substrate, wherein the fin structure comprises a first sacrificial layer, a first channel layer, a second sacrificial layer, and a second channel layer arranged in a stacking direction;
forming a dummy gate structure across the fin structure;
forming gate spacers on opposite sides of the dummy gate structure;
forming first source/drain epitaxial layers on opposite sides of the first channel layer and spaced apart from the second channel layer;
forming second source/drain epitaxial layers on opposite sides of the second channel layer and spaced apart from the first source/drain epitaxial layers;
removing the dummy gate structure, the first sacrificial layer, and the second sacrificial layer to form a gate trench defined by the gate spacers;
forming an oxynitride layer in the gate trench to surround the first channel layer;
forming a dipole layer comprising dipole dopants in the gate trench to surround the oxynitride layer;
performing an anneal process to drive the dipole dopants into the oxynitride layer; and
after performing the anneal process, sequentially depositing a high-k gate dielectric layer and a work function metal layer in the gate trench to form a gate structure.

2. The method of claim 1, wherein an amount of nitrogen atoms in the oxynitride layer is less than an amount of oxygen atoms in the oxynitride layer.

3. The method of claim 1, wherein a thickness of the oxynitride layer is less than about 50 angstrom.

4. The method of claim 1, further comprising removing an oxide layer in contact with the first channel layer to expose the first channel layer prior to forming the oxynitride layer.

5. The method of claim 4, wherein a thickness of the oxynitride layer is less than a thickness of the oxide layer.

6. The method of claim 1, wherein forming the oxynitride layer comprises:
forming an oxide layer to surround the first channel layer, wherein the oxide layer comprises dangling bonds; and
performing a microwave annealing process with nitrogen-containing plasma to the oxide layer to form the oxynitride layer.

7. The method of claim 6, wherein an amount of oxygen atoms in the oxide layer is greater than an amount of the dangling bonds in the oxide layer.

8. The method of claim 1, wherein the fin structure further comprises a third sacrificial layer between the first channel layer and the second sacrificial layer, and the method further comprises replacing the third sacrificial layer with a dielectric isolator between the first channel layer and the second channel layer.

9. The method of claim 8, wherein the oxynitride layer exposes a surface of the dielectric isolator.

10. A method comprising:
forming a bottom transistor over a substrate;
forming a fin structure over the bottom transistor, wherein the fin structure comprises a sacrificial layer and a channel layer over the sacrificial layer;
forming a dummy gate structure across the fin structure;
forming source/drain epitaxial layers on opposite sides of the channel layer and over the bottom transistor;
removing the dummy gate structure and the sacrificial layer;
forming a nitrogen-containing interfacial layer to surround the channel layer;
depositing a dipole layer to surround the nitrogen-containing interfacial layer;
performing an anneal process to drive dipole dopants into the nitrogen-containing interfacial layer; and
forming a high-k gate dielectric layer and a work function metal layer to surround the nitrogen-containing interfacial layer to form a gate structure.

11. The method of claim 10, wherein the nitrogen-containing interfacial layer is in contact with the channel layer.

12. The method of claim 10, further comprising forming an insulator layer over the bottom transistor prior to form the fin structure, wherein the nitrogen-containing interfacial layer is spaced apart from the insulator layer.

13. The method of claim 10, wherein after forming the gate structure, the dipole layer is in contact with the nitrogen-containing interfacial layer and the high-k gate dielectric layer.

14. The method of claim 10, wherein forming the nitrogen-containing interfacial layer comprises:
forming an oxide layer to surround the channel layer; and
providing nitrogen-containing plasma to the oxide layer to form the nitrogen-containing interfacial layer.

15. The method of claim 10, wherein the nitrogen-containing interfacial layer is formed at a temperature lower than about 800° C.

16. A device comprising:
a bottom transistor comprising:
a first channel layer;
a first gate structure surrounding the first channel layer, wherein the first gate structure comprises:
a first doped interfacial layer in contact with the first channel layer and comprising nitrogen and first dipole dopants; and
a first work function metal layer surrounding the first doped interfacial layer; and
first source/drain epitaxial structures on opposite sides of the first channel layer; and
a top transistor over the bottom transistor.

17. The device of claim 16, wherein the top transistor comprises:
a second channel layer;
a second gate structure surrounding the second channel layer, wherein the second gate structure comprises:
a second doped interfacial layer in contact with the second channel layer and comprising nitrogen and second dipole dopants; and
a second work function metal layer surrounding the second doped interfacial layer; and
second source/drain epitaxial structures on opposite sides of the second channel layer.

18. The device of claim 16, wherein the first gate structure further comprises a high-k gate dielectric layer between the first doped interfacial layer and the first work function metal layer.

19. The device of claim 16, wherein an amount of nitrogen atoms in the first doped interfacial layer is less than an amount of oxygen atoms in the first doped interfacial layer.

20. The device of claim 16, wherein a thickness of the first doped interfacial layer is less than about 50 angstrom.
